(19) United States
(12) Patent Application Publication
(10) Pub. No.: US 2023/0229078 A1
(43) Pub. Date: Jul. 20, 2023

(54) CHEMICAL LIQUID SUPPLY METHOD AND PATTERN FORMING METHOD

(71) Applicant: FUJIFILM Corporation, Tokyo (JP)

(72) Inventor: Masahiro YOSHIDOME, Shizuoka (JP)

(73) Assignee: FUJIFILM Corporation, Tokyo (JP)

(21) Appl. No.: 18/177,742

(22) Filed: Mar. 2, 2023

Related U.S. Application Data
(63) Continuation of application No. PCT/JP2021/031672, filed on Aug. 30, 2021.

(30) Foreign Application Priority Data
Sep. 8, 2020 (JP) 2020-150403

(51) Int. Cl. G03F 7/004; G03F 7/16; G03F 7/40

(52) U.S. Cl. CPC G03F 7/0048; G03F 7/16; G03F 7/40

(57) ABSTRACT

An object of the present invention is to provide a chemical liquid supply method capable of reducing the content of impurities in a chemical liquid. Another object of the present invention is to provide a pattern forming method.

The chemical liquid supply method according to an embodiment of the present invention is a chemical liquid supply method of supplying a chemical liquid containing an organic solvent through a pipe line that an apparatus for semiconductor devices comprises, the chemical liquid supply method having a gas pumping step of sending the chemical liquid by pressurization using a gas, in which a moisture content in the gas is 0.00001 to 1 ppm by mass with respect to a total mass of the gas.

### CROSS-REFERENCE TO RELATED APPLICATIONS

This application is a Continuation of PCT International Application No. PCT/JP2021/031672 filed on Aug. 30, 2021, which claims priority under 35 U.S.C. § 119(a) to Japanese Patent Application No. 2020-150403 filed on Sep. 8, 2020. The above applications are hereby expressly incorporated by reference, in their entirety, into the present application.

### BACKGROUND OF THE INVENTION

### 1. Field of the Invention

The present invention relates to a chemical liquid supply method and a pattern forming method.

### 2. Description of the Related Art

In a case where semiconductor devices are manufactured by a wiring forming process including photolithography, as a prewet solution, a resist solution, a developer, a rinsing solution, a stripper, a chemical mechanical polishing (CMP) slurry, a washing solution used after CMP, and the like, a chemical liquid containing a solvent (typically, an organic solvent) is used. In recent years, semiconductor device manufacturing in a node of 10 nm or less has been studied, and there has been a demand for a chemical liquid which has a higher defect inhibition performance suppressing the occurrence of defects on a wafer.

In order to obtain such a chemical liquid, it is important to reduce the content of impurities in the chemical liquid by precision filtration and to suppress the elution of impurities into the chemical liquid in an apparatus for semiconductor devices.

JP1999-162806A (JP-H11-162806A) describes an invention relating to a manufacturing method of a semiconductor device that supplies a resin solution by using a pressurized helium gas in forming a resin film by a spin coating method.

### SUMMARY OF THE INVENTION

With reference to the method described in JP1999-162806A (JP-H11-162806A), the inventors of the present invention conducted studies on a supply method having a gas pumping step of sending a chemical liquid by pressurization using a gas, among supply methods of sending a chemical liquid through a pipe line that an apparatus for semiconductor devices comprises. As a result, the inventors have found that there is a room for further improvement on the amount of impurities eluted into the chemical liquid sent from the pipe line by the gas pumping step.

An object of the present invention is to provide a chemical liquid supply method capable of reducing the amount of impurities eluted into a chemical liquid from a pipe line in a gas pumping step of sending a chemical liquid by using a gas. Another object of the present invention is to provide a pattern forming method.

In order to achieve the above objects, the inventors of the present invention carried out intensive examinations. As a result, the inventors have found that the objects can be achieved by the following constitution.

[1]

A chemical liquid supply method of supplying a chemical liquid containing an organic solvent through a pipe line that is provided in an apparatus for semiconductor devices, the chemical liquid supply method having a gas pumping step of sending the chemical liquid by pressurization using a gas, in which a moisture content in the gas is 0.00001 to 1 ppm by mass with respect to a total mass of the gas.

[2]

The chemical liquid supply method described in [1], in which a purity of the gas is 99.9% by volume or more.

[3]

The chemical liquid supply method described in [1] or [2], in which the moisture content in the gas is 0.005 to 0.5 ppm by mass with respect to the total mass of the gas.

[4]

The chemical liquid supply method described in any one of [1] to [3], in which the moisture content in the gas is 0.01 to 0.03 ppm by mass with respect to the total mass of the gas.

[5]

The chemical liquid supply method described in any one of [1] to [4], in which a purity of the gas is 99.999% by volume or more.

[6]

The chemical liquid supply method described in any one of [1] to [5], in which the gas includes at least one gas selected from the group consisting of nitrogen and argon.

[7]

The chemical liquid supply method described in any one of [1] to [6], in which the organic solvent is at least one compound selected from the group consisting of propylene glycol monomethyl ether, propylene glycol monoethyl ether, propylene glycol monopropyl ether, propylene glycol monomethyl ether acetate, ethyl lactate, methyl methoxypropionate, ethyl propionate, cyclopentanone, cyclohexanone, γ-butyrolactone, diisoamyl ether, butyl acetate, isoamyl acetate, isopropanol, 4-methyl-2-pentanol, 1-hexanol, dimethylsulfoxide, n-methyl pyrrolidone, diethylene glycol, ethylene glycol, dipropylene glycol, propylene glycol, ethylene carbonate, propylene carbonate, sulfolane, cycloheptanone, 2-heptanone, methyl ethyl ketone, hexane, and a combination of these.

[8]

A chemical liquid preparation step of chemical liquid supply method described in any one of [1] to [7], further having a chemical liquid preparation step of preparing the chemical liquid in a storage tank that is in communication with the pipe line, in which the gas pumping step is a step of sending the chemical liquid from the storage tank through the pipe line by introducing the gas into the storage tank.

[9]

The chemical liquid supply method described in any one of [1] to [8], further having a purification step of filtering the chemical liquid sent by the gas pumping step by using a filter.

[10]

The chemical liquid supply method described in [9], in which a total content of a Fe component, a Cr component, a Ni component, and an Al component in the chemical liquid filtered by the purification step is 0.04 to 1,200 ppt by mass with respect to a total mass of the chemical liquid.

[11]

The chemical liquid supply method described in [9] or [10], in which a total content of a Fe component, a Cr component, a Ni component, and an Al component in the chemical liquid filtered by the purification step is 0.2 to 400 ppt by mass with respect to a total mass of the chemical liquid.

[12]

The chemical liquid supply method described in any one of [9] to [11], in which a total content of a Fe component, a Cr component, a Ni component, and an Al component in the chemical liquid filtered by the purification step is 0.2 to 60 ppt by mass with respect to aa total mass of the chemical liquid.

[13]

The chemical liquid supply method described in any one of [9] to [12], in which a moisture content in the chemical liquid filtered by the purification step is 0.0005% to 0.03% by mass with respect to a total mass of the chemical liquid.

[14]

The chemical liquid supply method described in any one of [9] to [13], in which a moisture content in the chemical liquid filtered by the purification step is 0.001% to 0.02% by mass with respect to a total mass of the chemical liquid.

[15]

The chemical liquid supply method described in any one of [9] to [14], in which a moisture content in the chemical liquid filtered by the purification step is 0.001% to 0.01% by mass with respect to a total mass of the chemical liquid.

[16]

The chemical liquid supply method described in any one of [9] to [15], in which a content of dioctyl phthalate in the chemical liquid filtered by the purification step is 0.001 to 10 ppb by mass with respect to a total mass of the chemical liquid.

[17]

The chemical liquid supply method described in any one of [9] to [16], in which a content of dioctyl phthalate in the chemical liquid filtered by the purification step is 0.01 to 5 ppb by mass with respect to a total mass of the chemical liquid.

[18]

The chemical liquid supply method described in any one of [9] to [17], in which a content of dioctyl phthalate in the chemical liquid filtered by the purification step is 0.01 to 1 ppb by mass with respect to a total mass of the chemical liquid.

[19]

The chemical liquid supply method described in any one of [1] to [18], further having a gas purification step of purifying a raw material gas by using a gas filter, in which the gas purified by the gas purification step is used in the gas pumping step.

[20]

A pattern forming method having a pre-wetting step of bringing a pre-wet liquid into contact with a substrate, a resist film forming step of forming a resist film on the substrate by using a resist composition, a step of exposing the resist film, a development step of developing the exposed resist film by using a developer to form a resist pattern, and a rinsing step of bringing a rinsing liquid into contact with the substrate on which the resist pattern is formed, in which at least one liquid selected from the group consisting of the pre-wet liquid, the developer, and the rinsing liquid is the chemical liquid supplied by the supply method described in any one of [1] to [19].

According to the present invention, it is possible to provide a chemical liquid supply method capable of reducing the amount of impurities eluted into a chemical liquid from a pipe line in a gas pumping step of sending a chemical liquid by using a gas. In addition, according to the present invention, it is possible to provide a pattern forming method.

### BRIEF DESCRIPTION OF THE DRAWINGS

FIG. 1 is a schematic view showing an example of an apparatus used for a chemical liquid supply method.

### DESCRIPTION OF THE PREFERRED EMBODIMENTS

Hereinafter, the present invention will be specifically described.

The following configuration requirements will be described based on typical embodiments of the present invention in some cases, but the present invention is not limited to the embodiments.

In the present specification, a range of numerical values described using “to” means a range including the numerical values listed before and after “to” as a lower limit and an upper limit respectively.

In the present specification, in a case where there are two or more kinds of components corresponding to a certain component, “content” of such a component means the total content of the two or more kinds of components.

In the present specification, “preparation” means not only the preparation of a specific material by means of synthesis or mixing but also the preparation of a predetermined substance by means of purchase and the like.

In the present specification, “ppm” means “parts-per-million (10⁻⁶)”, “ppb” means “parts-per-billion (10⁻⁹)”, and “ppt” means “parts-per-trillion (10⁻¹²)”.

Furthermore, in the present specification, “radiation” means, for example, far ultraviolet, extreme ultraviolet (EUV), X-rays, electron beams, and the like. In addition, in the present specification, light means actinic rays or radiation. In the present specification, unless otherwise specified, “exposure” includes not only exposure by far ultraviolet, X-rays, EUV, and the like, but also lithography by particle beams such as electron beams or ion beams.

[Chemical Liquid Supply Method]

The chemical liquid supply method according to an embodiment of the present invention (hereinafter, also simply called “the present supply method”) is a method of supplying a chemical liquid containing an organic solvent through a pipe line that an apparatus for semiconductor devices comprises. The present supply method is characterized in that the method has a gas pumping step of sending a chemical liquid through a pipe line by pressurization using a gas, and that a moisture content in the gas is 0.01 to 1 ppm by mass with respect to a total mass of the gas.

Details of the mechanism through which the chemical liquid supply method reduces the amount of impurities eluted into the chemical liquid from the pipe line are unclear. According to the inventors of the present invention, presumably, performing the gas pumping step by using a gas having a moisture content reduced to a specific range may keep the content of moisture mixed into the chemical liquid from the gas low, which may suppress the elution and/or mixing of impurities into the chemical liquid from liquid contact portions of the pipe line and other members while allowing the moisture content in the gas to be equal to or more than a predetermined lower limit. The inventors assume that as a result, a trace of moisture may be mixed into the chemical liquid from the gas, which may suppress electrostatic destruction inducing the elution of impurities in liquid contact portions of the pipe line and other members.

Hereinafter, regarding the present invention, being excellently effective for reducing the amount of impurities eluted into the chemical liquid from the pipe line in the gas pumping step will be also described as “the effect of the present invention is excellent”.

First, a supply device used in the present supply method will be described, and then each step of the present supply method will be described.

[Supply Device]

The supply device (hereinafter, also simply called “supply device”) used in the present supply method is a device for semiconductor devices. In the present specification, “for semiconductor devices” means that the device is used for manufacturing of semiconductor devices.

The supply device may be a device that constitutes a part of a known semiconductor device manufacturing apparatus or a known semiconductor device treatment apparatus, and is preferably a device incorporated into a coater developer.

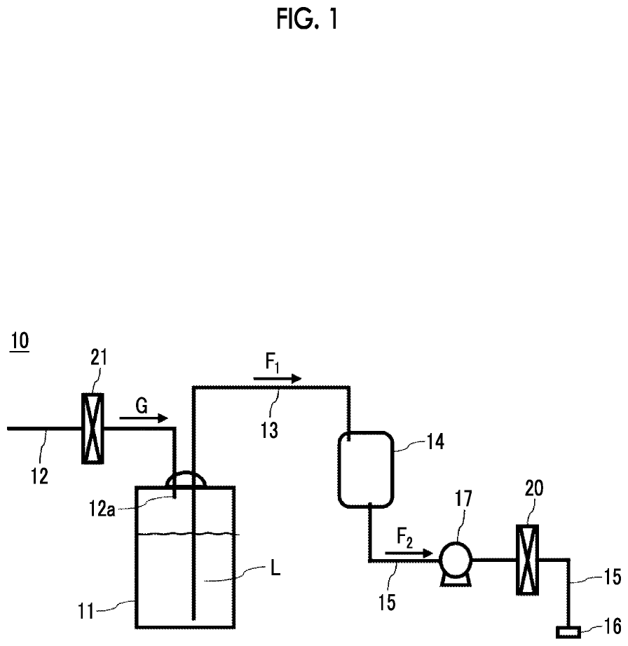

The supply device will be described with reference to a drawing. FIG. 1 is a schematic view showing an example of the configuration of the present device.

A supply device 10 shown in FIG. 1 is a device for semiconductor devices, and comprises a storage tank 11, a gas pipe 12, a pipe line 13, an intermediate tank 14, a pipe line 15, a discharge unit 16, a pump 17 and a filter unit 20 disposed on the pipe line 15, and a gas filter 21 disposed on the gas pipe 12.

In FIG. 1, F₁ and F₂ represent the moving direction of a liquid (chemical liquid) in the supply device 10, and G represents the moving direction of a pumping gas in the supply device 10.

The storage tank 11 is a container having a function of storing a chemical liquid. The storage tank 11 is connected to the gas pipe 12 and the pipe line 13 that penetrate the top of the storage tank 11 and are in communication with the inside of the storage tank 11. In addition, the storage tank 11 is provided with a chemical liquid introduction port (not shown in the drawing) for introducing a chemical liquid.

The gas pipe 12 is connected to a gas supply portion, which is not shown in the drawing, and the storage tank 11. As shown by an arrow G, the gas sent from the gas supply portion passes through the inside of the gas pipe 12 and is introduced into the storage tank 11 from a gas introduction port 12a disposed near the top of the storage tank 11.

The gas filter 21 is a filter that is disposed on the gas pipe 12 and has a function of removing moisture and/or impurities contained in the gas flowing in the gas pipe 12.

The pipe line 13 is connected to the storage tank 11 and the intermediate tank 14. An upstream end part of the pipe line 13 penetrates the top of the storage tank 11 and extends to the vicinity of the bottom of the storage tank 11. A downstream end part of the pipe line 13 penetrates the top of the intermediate tank 14 and extends to the upper part of the intermediate tank 14.

The chemical liquid stored in the storage tank 11 is sent to the intermediate tank 14 through the pipe line 13 as shown by the arrow F₁. As will be described later, the chemical liquid is sent by a gas pumping step of introducing a pumping gas into the storage tank 11 to pressurize the chemical liquid.

In the present specification, unless otherwise specified, the term “pipe line” means all parts in which the chemical liquid can exist between the storage tank 11 and the discharge unit 16.

The intermediate tank 14 is a container having a function of temporarily storing the chemical liquid sent from the storage tank 11. A pipe line 15 that is in communication with the discharge unit 16 is connected to the bottom of the intermediate tank 14.

As shown by the arrow F₂, the chemical liquid stored in the intermediate tank 14 is discharged from the discharge unit 16 through the pipe line 15. The pump 17 provided on the pipe line 15 has a function of sending the chemical liquid stored in the intermediate tank 14 to the discharge unit 16.

A filter cartridge having a filter is housed in the filter unit 20. The filter unit 20 has a function of filtering the chemical liquid passing through the pipe line 15 by using a filter. As the filter and filter cartridge constituting the filter unit 20, known filters and filter cartridges can be used. Details of the filter included in the filter unit will be explained in a purification step that will be described later.

The chemical liquid supplied by the supply device 10 is discharged from the discharge unit 16. The use of the discharged chemical liquid is not particularly limited. In a case where the discharge unit 16 has a function of jetting the chemical liquid, the chemical liquid may be jetted from the discharge unit 16 onto a wafer to perform various treatments, or the discharge unit 16 may be connected to a storage container for transporting and/or storing the chemical liquid such that the storage container is filled with the chemical liquid.

The material constituting the storage tank 11 and the intermediate tank 14 (hereinafter, both of these will be also simply collectively called “container”) that the supply device 10 comprises is not particularly limited, and may be an organic substance, an inorganic substance, or a combination of these. Specific examples of the material include a resin, glass, a metal, or a composite material of these (for example, a material composed of a metal base material and a glass or resin lining). The material can be arbitrarily selected from these depending on the type of chemical liquid to be accommodated. Particularly, it is preferable that at least a part of the liquid contact portion of the container (more preferably the entirety of the liquid contact portion and even more preferably the entirety of the container) contain an anticorrosive material, which will be described later, as a component.

For example, in a case where the container contains an anticorrosive material as a material component, examples of the form where at least a part of the liquid contact portion of the container contains an anticorrosive material as a component include a case where the container is a lining container having a base material and a coating layer (lining) which is disposed on the base material and contains an anticorrosive material as a material component (in this case, the base material may also contain an anticorrosive material as a material component), and the like.

More specifically, examples thereof include a container made of stainless steel, which will be described later, a container made of polytetrafluoroethylene, a lining container composed of a base material that consists of stainless steel and a coating layer that consists of polytetrafluoroethylene and is on the inner wall surface of the base material, and the like.

“Liquid contact portion” refers to a portion of the container that is likely to come into contact with the chemical liquid contained in the container.

The anticorrosive material is at least one kind of material selected from the group consisting of a nonmetal material and a metal material. As the metal material, an electropolished metal material is preferable.

As the nonmetal material, known materials can be used without particular limitation.

Examples of the nonmetal material include a polyolefin-based resin such as a polyethylene resin, a polypropylene resin, or a polyethylene-polypropylene resin; a fluorine-containing resin such as a tetrafluoroethylene resin, a tetrafluoroethylene-perfluoroalkyl vinyl ether copolymer, a tetrafluoroethylene-hexafluoropropylene copolymer resin, a tetrafluoroethylene-ethylene copolymer resin, a chlorotrifluoroethylene-ethylene copolymer resin, a vinylidene fluoride resin, a chlorotrifluoroethylene copolymer resin, or a vinyl fluoride resin, and the like. Among these, a fluorine-containing resin is preferable, and polytetrafluoroethylene (PTFE) is more preferable.

As the metal material, known materials can be used without particular limitation.

Examples of the metal material include a metal material in which the total content of chromium and nickel is greater than 25% by mass with respect to the total mass of the metal material. The total content of chromium and nickel is more preferably 30% by mass or more. The upper limit of the total content of chromium and nickel in the metal material is not particularly limited, but is preferably 90% by mass or less in general.

Examples of the metal material include stainless steel, carbon steel, alloyed steel, nickel chromium molybdenum steel, chromium steel, chromium molybdenum steel, manganese steel, and nickel chromium alloy. Among these, stainless steel is preferable.

As the stainless steel, known stainless steel can be used without particular limitation. Among these, an alloy with a nickel content of 8% by mass or more is preferable, and austenite-based stainless steel with a nickel content of 8% by mass or more is more preferable. Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), and SUS316L (Ni content: 12% by mass, Cr content: 16% by mass).

As the nickel-chromium alloy, known nickel-chromium alloys can be used without particular limitation. Among these, a nickel-chromium alloy is preferable in which the nickel content is 40% to 75% by mass and the chromium content is 1% to 30% by mass.

Examples of the nickel-chromium alloy include HASTELLOY (trade name, the same is true of the following description), MONEL (trade name, the same is true of the following description), and INCONEL (trade name, the same is true of the following description). More specifically, examples thereof include HASTELLOY C-276 (Ni content: 63% by mass, Cr content: 16% by mass), HASTELLOY C (Ni content: 60% by mass, Cr content: 17% by mass), and HASTELLOY C-22 (Ni content: 61% by mass, Cr content: 22% by mass).

Furthermore, as necessary, the nickel-chromium alloy may further contain at least one element selected from the group consisting of boron, silicon, tungsten, molybdenum, copper, and cobalt, in addition to the aforementioned alloy.

The method of electropolishing the metal material is not particularly limited, and examples thereof include the methods described in paragraphs “0011” to “0014” of JP2015-227501A, paragraphs “0036” to “0042” of JP2008-264929A, and the like.

Presumably, in a case where the metal material is electropolished, the chromium content in a passive layer on the surface thereof may become higher than the chromium content in the parent phase. Presumably, as a result, from a device where the liquid contact portion is formed of an electropolished metal material, a metal component containing metal atoms is unlikely to be eluted into the chemical liquid, which may make it possible to prepare a chemical liquid with a lower impurity content.

The metal material may have undergone buffing. As the buffing method, known methods can be used without particular limitation. The size of abrasive grains used for finishing the buffing is not particularly limited, but is preferably #400 or less because such grains make it easy to further reduce the surface asperity of the metal material. The buffing is preferably performed before the electropolishing.

The material constituting the pipe line 13 and the pipe line 15 that the supply device 10 comprises is not particularly limited, and a known pipe can be used. Examples of the pipe include a form comprising a pipe, a pump, a valve, and the like.

It is preferable that the liquid contact portion of the pipe lines 13 and 15 be formed of the anticorrosive material described above.

The supply device that can be used in the present supply method is not limited to the supply device 10 having the configuration described above. The supply device that can be used in the present supply method may have a configuration other than the configuration described above.

For example, although the supply device 10 shown in FIG. 1 comprises only one filter unit 20 on the pipe line 15, the supply device may include a plurality of filters. In this case, the plurality of filters that the supply device comprises may be arranged in series or arranged in a row in the chemical liquid transfer direction.

The supply device 10 shown in FIG. 1 has a configuration in which the purified chemical liquid that has flowed out of the filter unit 20 is transferred to the discharge unit 16. However, the supply device may have a configuration in which the chemical liquid that has flowed out of the filter unit 20 is sent back to the intermediate tank 14 and pass through the filter unit 20 again. This filtration method is called circulation filtration.

From the viewpoint of productivity and from the viewpoint of inhibiting impurities and the like captured by the filter from being mixed into the chemical liquid again, it is preferable that the chemical liquid be passed through the filter only once without being subjected to circulation filtration.

Although the filter unit 20 included in the supply device 10 comprises a filter and a filter cartridge, a filter that is not accommodated in the filter cartridge may also be used. The supply device may have, for example, an aspect in which the chemical liquid is passed through a filter in the form of a flat plate.

The supply device may comprise one filter or a plurality of filters on the pipe line connecting the storage tank and the intermediate tank. In a case where the supply device comprises a plurality of filters, the plurality of filters may be arranged in series or arranged in a row in the chemical liquid transfer direction. In the supply device, the chemical liquid may be passed only once through the filter provided on the pipe line connecting the storage tank and the intermediate tank. Alternatively, a return path for returning the chemical liquid from the downstream side of the filter to the storage tank may be provided, and the chemical liquid may be passed through the filter multiple times.

The supply device may not comprise a filter. In view of making it possible to further reduce the content of impurities in the chemical liquid, in the present supply method, it is preferable that a chemical liquid purification step, which will be described later, be performed using a supply device comprising a filter.

Next, each step of the present supply method will be described by exemplifying an embodiment in which the present supply method is performed using the supply device 10 shown in FIG. 1.

[Chemical Liquid Preparation Step]

First, a chemical liquid preparation step of introducing the chemical liquid to be supplied by the present supply method into the storage tank 11 is performed.

<Chemical Liquid>

The chemical liquid supplied by the present supply method is not particularly limited as long as the chemical liquid contains an organic solvent. It is possible to use known chemical liquids used for a treatment such as manufacturing of a semiconductor device.

(Organic Solvent)

The chemical liquid contains an organic solvent. The content of the organic solvent in the chemical liquid is not particularly limited. The content of the organic solvent with respect to the total mass of the chemical liquid is preferably 98% by mass or more, more preferably 99% by mass or more, and even more preferably 99.9% by mass or more. The upper limit of thereof is not particularly limited, but is preferably 99.999% by mass or less.

One kind of organic solvent may be used singly, or two or more kinds of organic solvents may be used in combination. In a case where two or more kinds of organic solvents are used in combination, the total content thereof is preferably within the above range.

In the present specification, an organic solvent means one liquid organic compound which is contained in the chemical liquid in an amount greater than 10,000 ppm by mass with respect to the total mass of the chemical liquid. That is, in the present specification, a liquid organic compound contained in an amount greater than 10,000 ppm by mass with respect to the total mass of the chemical liquid corresponds to an organic solvent.

In the present specification, “liquid” means that the compound stays in liquid form at 25° C. under atmospheric pressure.

The type of organic solvent is not particularly limited, and known organic solvents can be used.

Examples of the organic solvent include polar organic solvents such as alkylene glycol monoalkyl ether carboxylate, alkylene glycol monoalkyl ether, a lactic acid alkyl ester, alkyl alkoxypropionate, cyclic lactone (preferably having 4 to 10 carbon atoms), a monoketone compound which may have a ring (preferably having 4 to 10 carbon atoms), alkylene carbonate, alkoxyalkyl acetate, and alkyl pyruvate, and nonpolar organic solvents such as an unsubstituted liquid hydrocarbon.

Examples of the unsubstituted liquid hydrocarbon include linear, branched, or cyclic substituted hydrocarbons having 5 to 12 carbon atoms. As such hydrocarbons, n-pentane, n-hexane, n-heptane, n-octane, and n-nonane, n-decane, n-undecane, n-dodecane, isopentane, neopentane 5-ethyl-3-methyloctane, cyclopentane, cyclohexane, methylcyclopentane, 1-ethyl-3-methylcyclohexane, or a combination of these preferable, and n-hexane is more preferable.

Furthermore, as the organic solvent, those described in JP2016-057614A, JP2014-219664A, JP2016-138219A, and JP2015-135379A may be used.

As the organic solvent, propylene glycol monomethyl ether (PGMM), propylene glycol monoethyl ether (PGME), propylene glycol monopropyl ether (PGMP), propylene glycol monomethyl ether acetate (PGMEA), ethyl lactate (EL), methyl methoxypropionate (MPM), ethyl propionate, cyclopentanone (CyPn), cyclohexanone (CyHe), γ-butyrolactone (γBL), diisoamyl ether (DIAE), butyl acetate (nBA), isoamyl acetate (iAA), isopropanol (IPA), 4-methyl-2-pentanol (MIBC), 1-hexanol, dimethylsulfoxide (DMSO), n-methyl-2-pyrrolidone (NMP), diethylene glycol (DEG), ethylene glycol (EG), dipropylene glycol (DPG), propylene glycol (PG), ethylene carbonate (EC), propylene carbonate (PC), sulfolane, cycloheptanone, 2-heptanone (MAK), methyl ethyl ketone (MEK), hexane, or a combination of these is preferable.

Among these, PGMEA, ethyl propionate, CyPn, CyHe, nBA, iAA, MAK, MEK, propylene carbonate, hexane, or a combination of these is more preferable.

The type and content of the organic compound (including an organic solvent and an organic impurity which will be described later) contained in the chemical liquid can be measured using gas chromatography-mass spectroscopy (GC-MS). The measurement conditions are as described in Examples.

The chemical liquid may contain other components in addition to the above components. Examples of the other components include an organic impurity, water, and a metal component.

(Organic Impurity)

The chemical liquid may contain an organic impurity. The content of the organic impurity in the chemical liquid is not particularly limited. The content of the organic impurity with respect to the total mass of the chemical liquid is preferably 10,000 ppm by mass or less, and more preferably 1,000 ppm by mass or less. The lower limit thereof is not particularly limited, but is preferably 0.1 ppm by mass or more.

In the present specification, an organic impurity means an organic compound that is different from an organic solvent contained in the chemical liquid and contained in the chemical liquid at a content of 10,000 ppm by mass or less with respect to the total mass of the chemical liquid. That is, in the present specification, an organic compound contained in the chemical liquid at a content of 10,000 ppm by mass or less with respect to the total mass of the chemical liquid corresponds to an organic impurity and does not correspond to an organic solvent.

In a case where each of a plurality of organic compounds is contained in the chemical liquid at a content of 10,000 ppm by mass or less with respect to the total mass of the chemical liquid, each of the plurality of organic compounds corresponds to an organic impurity.

In many cases, the organic impurity is mixed into or added to the chemical liquid in the process of synthesizing, purifying, and/or transferring the organic solvent to be incorporated into the chemical liquid. Examples of such an organic impurity include a plasticizer, an antioxidant, and a compound derived from these (for example, a decomposition product).

In the process of synthesizing and purifying an organic solvent, sometimes a plasticizer is eluted into the organic solvent from the liquid contact portion of each unit (a reaction section, a distillation column, a filter unit, or the like) of the device (purification device) used for the purification.

In addition, in a case where an antioxidant is intentionally added to an organic solvent or in a case where a commercially available organic solvent is purchased and used, sometimes the organic solvent contains the antioxidant mixed in.

Among the organic impurities of these components, an organic impurity having a high boiling point (hereinafter, also described as “high-boiling-point organic impurity”) readily volatilizes, thus easily remains on the substrate surface as particles of organic residues, and is likely to cause defects in a semiconductor device.

Therefore, in the chemical liquid, the content of the high-boiling-point organic impurity (particularly, an organic impurity having a boiling point of 250° C. or higher) with respect to the total mass of the chemical liquid is preferably 1 ppm by mass or less, more preferably 50 ppb by mass or less, and even more preferably 10 ppb by mass or less. The lower limit thereof is not particularly limited, but is preferably 10 ppt by mass or more.

Examples of the high-boiling-point organic impurity include dioctyl phthalate (DOP, boiling point 385° C.), diisononyl phthalate (DINP, boiling point 403° C.), dioctyl adipate (DOA, boiling point 335° C.), dibutyl phthalate (DBP, boiling point 340° C.), and ethylene propylene rubber (EPDM, boiling point 300° C. to 450° C.).

Particularly, in view of further improving the impurity removing performance of the filter used in the purification step that will be described later, in the chemical liquid, the content of dioctyl phthalate (DOP) with respect to the total mass of the chemical liquid is preferably 0.001 to 10 ppb by mass, more preferably 0.01 to 5 ppb by mass, and even more preferably 0.01 to 1 ppb by mass.

(Metal Component)

The chemical liquid may contain a metal component.

In the present specification, “metal component” consists of a metal present as particles in the chemical liquid (that is, “metal particles”) and a metal present as ions in the chemical liquid (that is, “metal ions”).

The metal particles also mean, in addition to particles consist of a simple metal or an alloy, a compound composed of a metal, such as an oxide, a sulfide, or the like of a simple metal or an alloy, and another non-metal element bonded to the metal.

The metal ions mean simple metal ions and complex ions (for example, an ammine complex, a cyano complex, a halogeno complex, a hydroxyl complex, and the like).

In the present specification, in a case where the there is a metal component (metal particles and metal ions) containing a certain metal element M, “content of the metal component” means the content of only the metal component containing the metal element M.

In a case where the metal component contains two or more kinds of metal elements, the content of only a metal element having the highest content is calculated as the content of the metal component. That is, the content of a metal component containing two or more kinds of metal elements is not included the contents of two or more kinds of metal components in duplicate. More specifically, the content of a metal component containing Fe and Cr is not included in both the content of the Fe component and the content of the Cr component.

In the present specification, “content of an Fe component” refers to the total content of metal particles (Fe particles) having the highest Fe content among the metal elements and metal ions (Fe ions) having the highest Fe content among the metal elements. “Content of a Cr component” refers to the total content of metal particles (Cr particles) having the highest Cr content among the metal elements and metal ions (Cr ions) having the highest Cr content among the metal elements. “Content of a Ni component” refers to the total content of metal particles (Ni particles) having the highest Ni content among the metal elements and metal ions (Ni ions) having the highest Ni content among the metal elements. “Content of an Al component” refers to the total content of metal particles (Al particles) having the highest Al content among the metal elements and metal ions (Al ions) having the highest Al content among the metal elements.

In view of further improving the impurity removing performance of the filter used in the purification step which will be described later, in the chemical liquid, the total content of the Fe component, the Cr component, the Ni component, and the Al component (hereinafter, these components will be also called “specific metal components”) with respect to the total mass of the chemical liquid is preferably 0.04 to 1,200 ppt by mass, more preferably 0.2 to 400 ppt by mass, and even more preferably 0.2 to 60 ppt by mass.

Presumably, the impurity removal performance of the filter may be improved for the following reason. That is, in a case where the total content of the specific metal components in the chemical liquid is equal to or less than the aforementioned upper limit, static electricity is likely to be accumulated in the filter, and the removal performance of the filter may be improved. In contrast, in a case where the total content of the specific metal components is equal to or more than the aforementioned lower limit, electrostatic destruction in the liquid contact portion of the filter is suppressed, and the removal performance of the filter may be improved.

The total content of all the metal components in the chemical liquid is preferably 5,000 ppt by mass (5 ppb by mass) or less, and more preferably 500 ppt by mass or less. The lower limit is not particularly limited, and may be equal to or less than the detection limit.

In the chemical liquid, the content of a metal component other than the specific metal components per metal element is preferably 50 ppt by mass or less, and more preferably 10 ppt by mass or less. The lower limit is not particularly limited. The lower limit may be equal to or less than the detection limit, and is preferably 0.001 ppt by mass or more.

The type and content of the metal component in the chemical liquid can be measured by the Single Nano Particle Inductively Coupled Plasma Mass Spectrometry (SP-ICP-MS).

The device used in SP-ICP-MS is the same as the device used in general inductively coupled plasma mass spectrometry (ICP-MS). The only difference between SP-ICP-MS and ICP-MS is how to analyze data. With SP-ICP-MS, data can be analyzed using commercial software.

With ICP-MS, the content of a metal component as a measurement target is measured regardless of the way the metal component is present. Accordingly, the total mass of metal particles and metal ions as a measurement target is quantified as the content of the metal component.

The type and content of the metal component in the chemical liquid can be measured by the method described in Examples, by using, for example, Agilent 8800 triple quadrupole inductively coupled plasma mass spectrometry (ICP-MS, for semiconductor analysis, option #200) manufactured by Agilent Technologies, Inc. as a device for SP-ICP-MS.

(Water)

The chemical liquid may contain water.

The moisture content (content of water) in the chemical liquid is not particularly limited. In view of further improving the removal performance of the filter used in the purification step which will be described later, the moisture content with respect to the total mass of the chemical liquid is preferably 0.0005% to 0.03% by mass, more preferably 0.001% to 0.02% by mass, and even more preferably 0.001% to 0.01% by mass.

Presumably, the removal performance of the filter may be improved for the following reason. That is, in a case where the moisture content in the chemical liquid is equal to or less than the aforementioned upper limit, the amount of metal components eluted into the chemical liquid from a member such as a pipe line is reduced, electricity is likely to be accumulated in the filter, and the removal performance of the filter may be improved. In contrast, in a case where the moisture content is equal to or more than the aforementioned lower limit, electrostatic destruction in the liquid contact portion of the filter is suppressed, and the removal performance of the filter may be improved.

The content of water in the chemical liquid means the content of moisture measured using a device which adopts the Karl Fischer titration method as the principle of measurement.

<Preparation of Chemical Liquid>

The method of preparing the aforementioned chemical liquid is not particularly limited. However, in order to prepare a chemical liquid having an organic impurity content, a metal component content, and a water content in a desired range, it is preferable to prepare the chemical liquid by performing the following purification step on a liquid to be purified containing an organic solvent.

There is no particular limit on the timing of performing the purification step. The purification step may be performed before or after the manufacturing of the organic solvent contained in the chemical liquid. In a case where the chemical liquid contains two or more kinds of organic solvents, the organic solvents may be mixed together after being separately purified or may be purified after being mixed together.

The purification step may be performed before or after two or more kinds of the organic solvents are mixed together. The purification step may be performed only once, or may be performed twice or more.

An example of the purification step will be shown below. In the following description, “liquid to be purified” is a purification target in the purification step.

Examples of the purification step include an ion exchange treatment of performing an ion exchange treatment on the liquid to be purified, a dehydration treatment of dehydrating the liquid to be purified, an organic impurity-removing treatment of removing organic impurities of the liquid to be purified, and a filtering treatment using a metal ion adsorption member for the purpose of removing metal ions.

With the ion exchange treatment, it is possible to remove an ion component (for example, a metal component or the like) in the liquid to be purified.

In the ion exchange treatment, ion exchange means such as an ion exchange resin is used. The ion exchange resin may be any of a cation exchange resin or an anion exchange resin provided in the form of a single bed, a cation exchange resin and an anion exchange resin provided in the form of a double bed, and a cation exchange resin and an anion exchange resin provided in the form of a mixed bed.

As the ion exchange resin, in order to reduce the elution of moisture from the ion exchange resin, it is preferable to use a dry resin containing as little water as possible. As such a dry resin, commercially available products can be used. Examples thereof include 15JS-HG⋅DRY (trade name, dry cation exchange resin, moisture content of 2% or less) manufactured by ORGANO CORPORATION), and MSPS2-1⋅DRY (trade name, mixed-bed resin, moisture content of 10% or less).

With the dehydration treatment, it is possible to remove water in the liquid to be purified. In a case where zeolite (particularly, a molecular sieve (trade name) manufactured by UNION SHOWA K.K.), which will be described later, or the like is used in the dehydration treatment, olefins can also be removed.

Examples of dehydration means used in the dehydration treatment include a dehydrating film, water adsorbent insoluble in a liquid to be purified, an aerating purge device using a dried inert gas, a heating or vacuum heating device, and the like.

In a case where a dehydrating film is used, membrane dehydration by pervaporation (PV) or vapor permeation (VP) is performed. The dehydrating film is composed as, for example, a water-permeable film module. As the dehydrating film, it is possible to use films consisting of polymer-based materials, such as a polyimide-based material, a cellulose-based material, and a polyvinyl alcohol-based material, or an inorganic material such as a zeolite.

The water adsorbent is used by being added to the liquid to be purified. Examples of the water adsorbent include zeolite, diphosphorus pentoxide, silica gel, calcium chloride, sodium sulfate, magnesium sulfate, anhydrous zinc chloride, fuming sulfuric acid, and soda lime.

With the organic impurity-removing treatment, it is possible to remove high-boiling-point organic impurity and the like (including organic substances having a boiling point of 300° C. or higher) contained in the liquid to be purified.

The organic impurities can be removed by organic impurity-removing means, for example, an organic impurity adsorption member provided with an organic impurity adsorption filter capable of adsorbing organic impurities. In many cases, the organic impurity adsorption member comprises the aforementioned organic impurity adsorption filter and a substrate on which the impurity adsorption filter is fixed.

From the viewpoint of improving the organic impurity adsorption performance, it is preferable that the organic impurity adsorption filter has the skeleton of an organic substance, which can interact with the organic impurities, on the surface thereof (in other words, it is preferable that the surface of the organic impurity adsorption filter is modified with the skeleton of an organic substance which can interact with the organic impurities). One of the examples of “has the skeleton of an organic substance, which can interact with the organic impurities, on the surface thereof” include a form in which the skeleton of an organic substance which can interact with the organic impurities is provided on the surface of a substrate constituting the organic impurity adsorption filter that will be described later.

Examples of the skeleton of an organic substance which can interact with the organic impurity include a chemical structure which can react with the organic impurities to make the organic impurities captured by the organic impurity adsorption filter. More specifically, in a case where the organic impurities include dioctyl phthalate, diisononyl phthalate, dioctyl adipate, or dibutyl phthalate, examples of the organic skeleton include a benzene ring skeleton. In addition, in a case where the organic impurities include ethylene propylene rubber, examples of the skeleton of an organic substance include an alkylene skeleton. Furthermore, in a case where the organic impurities include a long-chain n-alkyl alcohol (corresponding to a structural isomer in a case where the long-chain 1-alkyl alcohol is used as a solvent), examples of the skeleton of an organic substance include an alkyl group.

Examples of the substrate (material) of organic impurity adsorption filter include cellulose supporting activated carbon, diatomite, nylon, polyethylene, polypropylene, polystyrene, and a fluororesin.

Furthermore, as an organic impurity-removing filter, it is also possible to use a filter prepared by fixing activated carbon to nonwoven fabric described in JP2002-273123A and JP2013-150979A.

The organic impurity-removing treatment is not limited to the aforementioned aspect in which the organic impurity adsorption filter capable of adsorbing organic impurities is used, and may be, for example, an aspect in which organic impurities are physically captured. Organic impurities having a boiling point of 250° C. or higher, which is relatively high boiling point, are coarse in many cases (for example, a compound having 8 or more carbon atoms). Therefore, it is possible to capture such organic impurities by using a filter having a pore diameter of about 1 nm.

For example, the structure of dioctyl phthalate is larger than 10 Å (=1 nm). Therefore, in a case where an organic impurity-removing filter having a pore diameter of 1 nm is used, dioctyl phthalate cannot pass through the pores of the filter. Accordingly, dioctyl phthalate is physically captured by the filter and removed from the liquid to be purified.

In this way, the organic impurity can be removed not only by a chemical interaction but also by a physical removing method. Here, in this case, a filter having a pore diameter of 3 nm or more is used as a “filtration member”, and a filter having a pore diameter less than 3 nm is used as an “organic impurity-removing filter”.

Examples of the filtering treatment using the metal ion adsorption member include filtering using a metal ion adsorption member comprising a metal ion adsorption filter.

The metal ion adsorption member comprises at least one metal ion adsorption member. The metal ion adsorption member may have a configuration in which a plurality of metal ion adsorption filters is stacked depending on the intended purification level. In many cases, the metal ion adsorption member comprises the metal ion adsorption filter and a substrate on which the metal ion adsorption filter is fixed.

The metal ion adsorption filter comprises a function of adsorbing metal ions in the liquid to be purified. In addition, the metal ion adsorption filter is preferably a filter capable of exchanging ions.

The metal ions to be adsorbed is not particularly limited, but are preferably Fe, Cr, Ni, Pb, or Al because these are likely to cause defects in a semiconductor device.

From the viewpoint of improving the metal ion adsorption performance, it is preferable that the metal ion adsorption filter have an acid group on the surface thereof. Examples of the acid group include a sulfo group, a carboxyl group, and the like.

Examples of the substrate (material) constituting the metal ion adsorption filter include cellulose, diatomite, nylon, polyethylene, polypropylene, polystyrene, a fluororesin, and the like.

The purification treatment performed in the purification step is not limited to the aforementioned treatment. For example, a purification treatment may be performed which is selected from the group consisting of a distillation treatment using a distillation device, a filtration treatment for removing coarse particles, and a metal component adsorption/purification treatment using silicon carbide described in WO2012/043496A.

In addition, as the purification step, each of the above treatments may be performed alone, or a plurality of the above treatments may be performed in combination. Furthermore, each of the treatments may be performed once or multiple times.

In the present supply method, a commercially available high-purity grade organic solvent (particularly, an organic solvent having a low content of organic impurities, metal components, and water) may also be used.

(Electricity Removing Treatment)

Before the chemical liquid is used in the present supply method, an electricity removing treatment for reducing the charge potential of the chemical liquid may be performed on the chemical liquid.

The electricity removing treatment is not particularly limited, and known electricity removing methods can be used. Examples thereof include a method of bringing the chemical liquid into contact with a conductive material.

The contact time for which the chemical liquid is brought into contact with a conductive material is preferably 0.001 to 60 seconds, more preferably 0.001 to 1 second, and even more preferably 0.01 to 0.1 seconds. Examples of the conductive material include stainless steel, gold, platinum, diamond, and glassy carbon.

Examples of the method of bringing the chemical liquid into contact with a conductive material include a method of disposing a grounded mesh consisting of a conductive material in the interior of a pipe line and passing the chemical liquid through the mesh.

It is preferable that the chemical liquid be prepared under an airtight condition in an inert gas atmosphere where the water is highly unlikely to be mixed into the chemical liquid. In order to suppress the mixing of moisture as much as possible, it is more preferable that the chemical liquid be prepared in an inert gas atmosphere where a dewpoint is −70° C. or lower. This is because, in an inert gas atmosphere of −70° C. or lower, the water concentration in the gas phase is 2 ppm by mass or less, and thus water is unlikely to be mixed into the chemical liquid.

The chemical liquid may be temporarily stored in a container until the chemical liquid is used in the present supply method. As the container for storing the chemical liquid, known containers can be used without particular limitation.

As the container storing the chemical liquid, a container for manufacturing semiconductor devices is preferable which has a high internal cleanliness and hardly causes elution of impurities.

Examples of the usable container specifically include a “CLEAN BOTTLE” series manufactured by AICELLO CORPORATION and “PURE BOTTLE” manufactured by KODAMA PLASTICS Co., Ltd., but the container is not limited to these.

It is preferable that the inside of the container be washed before the container is filled with the chemical liquid. As the liquid used for washing, the aforementioned chemical liquid or a liquid prepared by diluting the chemical liquid is preferable. After being prepared, the chemical liquid may be bottled using a container, such as a gallon bottle or a quart bottle, and transported and/or stored. A glass material or other materials may be used in the gallon bottle.

In order to prevent changes in the components of the chemical liquid, the inside of the container may be purged with an inert gas (such as nitrogen or argon) having a purity of 99.99995% by volume or higher. Particularly, a gas with a low moisture content is preferable. Although the chemical liquid may be transported and stored at room temperature (25° C.), in order to prevent deterioration, the temperature may be controlled in a range of −20° C. to 30° C.

[Gas Pumping Step]

The present supply method has a gas pumping step of sending the chemical liquid by pressurization using a gas.

In the supply device 10 shown in FIG. 1, a gas is introduced into the storage tank 11 through the gas pipe 12, which increases the pressure of the gas accumulated in the head space in the upper portion of the storage tank 11 and pressurizes a chemical liquid L stored in the storage tank 11. The chemical liquid L is pressurized in this way, and a pressure difference is made between the inside of the storage tank 11 and the inside of the intermediate tank 14. As a result, the chemical liquid L stored in the storage tank 11 is sent (pumped) to the intermediate tank 14 through the pipe line 13.

The position in the pipe line into which the pumping gas is introduced may be a position other than the inside of the storage tank, as long as the chemical liquid in the pipe line can be sent by pressurization of the chemical liquid. For example, the position may be inside of the pipe lines 13 and 15.

The moisture content in the gas used in the gas pumping step of the present supply method (hereinafter, also called “pumping gas”) is 0.00001 to 1 ppm by mass with respect to the total mass of the pumping gas. Using a gas having a moisture content reduced to a specific range as described above makes it possible to reduce the content of impurities (particularly, an organic impurity) contained in the chemical liquid pumped by the gas pumping step.

Furthermore, setting the moisture content of the pumping gas to 0.00001% by mass or more makes it possible to reduce the content of impurities (particularly, an organic impurity) contained in the chemical liquid pumped by the gas pumping step. Details of the mechanism are unclear. According to the inventors of the present invention, presumably, because the electrostatic destruction of the liquid contact portion resulting from the accumulation of static electricity in the liquid contact portion of a member such as a pipe line can be suppressed, the content of impurities could be reduced.

From the above viewpoint, the moisture content of the pumping gas with respect to the total mass of the pumping gas is preferably 0.005 to 0.5 ppm by mass, more preferably 0.01 to 0.3 ppm by mass, and even more preferably 0.01 to 0.03 ppm by mass.

In addition, in view of further improving the effect of the present invention and making is possible to further reduce the content of impurities in the chemical liquid, the purity of the pumping gas is preferably 99.9% by volume (3N) or more, and more preferably 99.999% by volume (5N) or more.

The upper limit is not particularly limited, and may be equal to or more than the detection limit.

The purity of the pumping gas means a volume ratio (percentage) of the content of a gas (total content in a case where two or more kinds of gases are used), which is in a gas state in the atmosphere at 25° C. and has a content of 99% by volume or more with respect to the total volume of the pumping gas, to the content of components of the pumping gas except for water (water vapor).

That is, in the present specification, a component having a content less than 1% by volume with respect to the total volume of the pumping gas corresponds to an impurity gas.

Examples of the type of pumping gas include an inert gas such as nitrogen, argon, or helium, and dry air. In view of being capable of further suppressing the elution of impurities from the pipe line, an inert gas is preferable, nitrogen or argon is more preferable, and argon is even more preferable.

As the pumping gas, one kind of the aforementioned gas may be used alone, or two or more kinds of aforementioned gases may be used in combination.

The moisture content in the pumping gas, the purity of the pumping gas, and the type of pumping gas can be measured using an atmospheric pressure ionization mass spectrometer (API-MS) (for example, manufactured by NIPPON API CO., LTD.).

<Gas Purification Step>

The method of preparing the pumping gas, which is used in the present supply method and has a moisture content in the above range, is not particularly limited. It is preferable to perform a gas purification step of removing water (water vapor) contained in a raw material gas to prepare the pumping gas.

Examples of more specific aspects of the gas purification step include an aspect in which a raw material gas is passed through the gas filter 21 disposed on the gas pipe 12 in the supply device 10 shown in FIG. 1 to prepare a pumping gas and the prepared pumping gas is introduced into the storage tank 11.

Examples of the gas filter used in the gas purification step include an in-line gas filter such as “Wafergard (registered trademark) III NF-750” manufactured by Entegris Inc.

The raw material gas may be purified in advance to prepare the pumping gas, before the pumping gas is supplied to the supply device. The method of purifying the raw material gas in advance is not particularly limited, and examples thereof include a method of treating the raw material gas by using a known adsorbent such as molecular sieve, alumina, silica gel, or silica-alumina.

The supply pressure and flow rate of the gas in the gas pumping step are not particularly limited, and may be appropriately set depending on the liquid feeding conditions and the pressure resistance of each member such as the storage tank, the gas pipe, and the control valve.

Regarding the gas supply pressure in the gas pumping step, the pressure of the gas pressurizing the chemical liquid is preferably 0.01 to 0.34 MPa.

<Pump Transfer Step>

The supply device used in the present supply method may be provided with a section where a pump provided on the pipe line is used to transfer the chemical liquid in the pipe line. That is, the present supply method may have a pump transfer step of transferring the chemical liquid by using a pump.

The section in the pipe line where the pump transfer step is performed (pump transfer section) may overlap with or be different from the section in the pipe line where the gas pumping step is performed (gas pumping section).

In the case of the supply device 10 shown in FIG. 1, the pipe line 13 connecting the storage tank 11 to the intermediate tank 14 is the gas pumping section, and the pipe line 15 connecting the intermediate tank 14 to a discharge port 16 is the pump transfer section.

In a case where the supply device in which the present supply method is implemented is a treatment device that discharges the chemical liquid onto a wafer to perform various types of treatment, in the pipe line that the supply device comprises, a section including a downstream end of the pipe line connecting a jetting portion having a function of jetting the chemical liquid on a wafer is preferably the aforementioned pump transfer section. That is, it is preferable that the jetting of the chemical liquid from the supply device be performed using a pump. Performing the transfer of the chemical liquid by using a pump makes it possible to accurately control the amount of the chemical liquid jetted to a wafer.

Examples of the type of pump used in the pump transfer step include an electric submersible pump (electrical pump), a diaphragm pump, and a centrifugal pump (such as a magnetic pump).

In a case where a pump and a filter are provided on the pump transfer section, the position where the pump is provided is not particularly limited. The pump may be provided on the upstream or downstream side from the filter on the pipe line, and is preferably provided on the upstream side from the filter. In one pump transfer section, one pump may be used, or two or more pumps may be used in combination.

The supply pressure of the chemical liquid in the pump transfer step is not particularly limited. The internal pressure of the pipe line on the upstream side of the filter is preferably 0.00010 to 1.0 MPa, and more preferably 0.01 to 0.34 MPa.

The filtration pressure affects the filtration accuracy. Therefore, it is preferable that the pulsation of the supply pressure of the chemical liquid applied to the filter be as low as possible. Examples of a method of reducing the pulsation of the supply pressure of the chemical liquid include a method of using an adjusting valve and/or a damper disposed in the pipe line on the upstream side of the filter.

<Purification Step>

Just as the supply device 10 shown in FIG. 1 comprises the filter unit 20 on the pipe line 15, the supply device used in the present supply method may include a filter having a function of filtering and purifying the chemical liquid on the pipe line. That is, the present supply method may have a purification step of filtering the chemical liquid in the pipe line by using a filter.

It is preferable that the present supply method have the purification step, for the following reason. In the present supply method which is a chemical liquid supply method having the aforementioned gas pumping step, in a case where the chemical liquid pumped using a pumping gas having a specific moisture content is filtered by being passed through a filter, the impurity removing performance of the filter is improved, and the impurity content in the purified chemical liquid can be further reduced.

Details of the mechanism through which the impurity removing performance of the filter is improved are unclear. According to the inventors of the present invention, presumably, in a case where the gas pumping step is performed using a gas having a moisture content reduced to a specific range, the amount of moisture mixed into the chemical liquid from the gas may be reduced, and the elution of impurities into the chemical liquid from the liquid contact portions of the pipe line and other members may be suppressed. As a result, static electricity is likely to be accumulated in the filter, which may improve the impurity removing performance of the filter. In contrast, in a case where the moisture content in the gas is set to be equal to or more than a predetermined lower limit, a trace of moisture may be mixed into the chemical liquid from the gas, and the electrostatic destruction of the filter that leads to the elution and/or mixing of impurities may be suppressed.

Particularly, it is more preferable that the present supply method have a purification step of filtering the chemical liquid sent by the gas pumping step by using a filter, because then the effect of improving the removing performance of the filter is more markedly exhibited.

In the supply device 10, the purification step is performed as follows.

The chemical liquid stored in the intermediate tank 14 passes through the pipe line 15 by the pump 17 and is sent to the filter unit 20 having a filter. The chemical liquid is filtered and purified while passing through the filter included in the filter cartridge housed in the filter unit 20. The purified chemical liquid flowing out of the filter cartridge 20 passes through the pipe line 15 and discharged from the discharge port 16.

One filter or a plurality of filters may be used in the purification step. In a case where a plurality of filters is used, the filters may be arranged in series or arranged in a row in the chemical liquid transfer direction.

In addition, a circulation filtration may be performed in which the purified chemical liquid that has passed through the filter may be returned to the storage tank or the intermediate tank and repeatedly passed through the filter. From the viewpoint of productivity and from the viewpoint of suppressing the mixing of impurities, the chemical liquid may be passed through the filter only once without being subjected to circulation filtration.

(Filter)

Hereinafter, the filter used for purifying (filtering) the chemical liquid in the purification step will be specifically described.

The pore diameter of the filter is not particularly limited, as long as the pore diameter is generally used for filtering a chemical liquid. The pore diameter of the filter is preferably 20 nm or less, more preferably 5 nm or less, and even more preferably 2 nm or less. The lower limit thereof is not particularly limited, but is preferably 1 nm or more.

In a case where the supply device comprises a plurality of filters, it is preferable that the pore diameter of at least one filter is within the above range.

In the present specification, the pore diameter of a filter means a pore diameter determined by the bubble point of isopropanol (IPA) or HFE-7200 (“NOVEC 7200”, manufactured by 3M, hydrofluoroether, C₄F₉OC₂H₅).

The material constituting the filter is not particularly limited, and examples thereof include a polyolefin (including a high density polyolefin and an ultra-high-molecular-weight polyolefin) such as polyethylene (PE) or polypropylene (PP); a polyamide such as nylon (including nylon 6 and nylon 66); a polyimide; a polyamideimide; a polyester such as polyethylene terephthalate; polyether sulfone; cellulose; a fluorine resin such as polytetrafluoroethylene (PTFE) or perfluoroalkoxyalkane; and derivatives of the above polymers (or resins).

Among these, a material consisting of at least one polymer selected from the group consisting of a polyolefin, a polyamide, a polyimide, a polyamideimide, a polyester, a polysulfone, cellulose, a fluororesin, and derivatives of these is preferable. In view of being capable of further reducing the impurity content in the chemical liquid, polyethylene, polypropylene, nylon, or a fluororesin is more preferable, and PTFE is even more preferable.

Examples of the material constituting the filter also include diatomite and glass.

The material constituting the filter may be derivatives of the aforementioned polymers. Examples of the derivatives include a derivative obtained by introducing an ion exchange group into the above polymer by a chemical modification treatment.

Examples of the ion exchange group include a cation exchange group such as a sulfonic acid group, a carboxy group, or a phosphoric acid group, and an anion exchange group such as a secondary, tertiary, or quaternary ammonium group. The method of introducing ion exchange groups into the polymer is not particularly limited, and examples thereof include a method of reacting a compound, which has ion exchange groups and polymerizable groups, with the polymer such that a graft polymer is made.

For example, in a case where a polyolefin (such as polyethylene or polypropylene) is used, the polyolefin is irradiated with ionizing radiation (such as α-rays, β-rays, γ-rays, X-rays, an electron beams) such that an active moiety (radical) is generated in the molecular chain of the polyolefin. After being irradiated, the polyolefin is immersed in a monomer-containing solution such that the monomer is graft-polymerized. As a result, a product is generated in which the monomer is bonded to the polyolefin as a side chain by graft polymerization. By bringing the polyolefin fiber having the polymer as a side chain into contact with a compound having an anion exchange group or a cation exchange group to cause a reaction between the polyolefin and the compound, an end product is obtained in which the ion exchange group is introduced into the monomer of the graft-polymerized side chain. In such an end product, an ion exchange group is introduced not into the polyolefin fiber which is the main chain, but into the monomer of the side chain graft-polymerized with the main chain.

Furthermore, the filter may be constituted with woven cloth or nonwoven fabric, in which ion exchange groups are formed by a radiation graft polymerization method, combined with glass wool, woven cloth, or nonwoven fabric that is conventionally used.

Furthermore, the filter may have undergone a surface treatment other than chemical modification. As the surface treatment method, known methods can be used without particular limitation. Examples of the surface treatment method include a plasma treatment, a hydrophobic treatment, coating, a gas treatment, and sintering.

The plasma treatment is preferable because the surface of the filter is made hydrophilic by this treatment. Although the water contact angle on the surface of each filter made hydrophilic by the plasma treatment is not particularly limited, a static contact angle measured at 25° C. by using a contact angle meter is preferably 60° or less, more preferably 50° or less, and even more preferably 30° or less.

The pore structure of the filter is not particularly limited, and may be appropriately selected depending on the form of impurities contained in the chemical liquid. The pore structure of the filter means a pore diameter distribution, a positional distribution of pores in the filter, a pore shape, and the like, and varies with the manufacturing method of the filter.

For example, there is a difference in pore structure between a porous membrane that is formed by sintering of powder of a resin or the like and a fiber membrane that is formed by a method such as electrospinning, electroblowing, or melt blowing.

The critical surface tension of the filter is not particularly limited, and can be appropriately selected depending on the impurities to be removed.

In the purification step, the temperature at which the chemical liquid is passed through the filter is preferably 0° C. to 50° C., and more preferably 0° C. to 25° C.

In the purification step, the filtering speed of the chemical liquid passing through the filter that is represented by a flow rate (L/min) per filtration area of the filter is preferably 0.6 L/min/m² or more, more preferably 0.75 L/min/m² or more, and even more preferably 1.0 L/min/m² or more.

For the filter, an endurable differential pressure for assuring the filter performance (assuring that the filter will not be broken) is set. In a case where the endurable differential pressure is high, by increasing the filtering pressure, the filtering speed can be increased. The upper limit of the filtering speed depends on the endurable differential pressure of the filter, and is preferably 10.0 L/min/m² or less.

<Washing Step>

It is preferable that the supply device used in the present supply method be subjected to a washing step of cleaning the liquid contact portion of each member in the device before performing the present supply method. Washing each member (particularly, a filter) makes it possible to further reduce the impurity content in the chemical liquid supplied.

Examples of specific methods of the washing step include a method of using a washing solution instead of the chemical liquid and transferring the washing solution in the pipe line according to the method described in the above section of Gas pumping step or Pump transfer step.

Examples of the method of washing the filter include a method of immersing the filter in a washing solution, a method of causing a washing solution to flow through the filter, and a method of using these methods in combination.

The washing solution is not particularly limited, and an organic solvent is preferable.

The organic solvent to be used as the washing solution is as described above as the organic solvent contained in the chemical liquid, including preferred aspects thereof.

The washing solution used in the washing step may be the same as or different from the chemical liquid sent by the gas pumping step. The washing solution is preferably the same as the chemical liquid, because then a rinsing treatment using the chemical liquid is not required.

The method of transferring the washing solution in the washing step is not particularly limited. It is possible to allow the washing solution to flow in the pipe line or to pass the washing solution through the filter, according to the method described above as the gas pumping step and/or the pump transfer step.

In the washing step, there is no particular limit on the supply pressure of the washing solution in a case where the washing solution is passed through the filter. For example, the internal pressure of the pipe line on the upstream side from the filter may be 0.0001 to 1.0 MPa.

The flow rate of the washing solution passed through the filter in the washing step is preferably 0.6 to 10.0 L/min/m² in terms of a flow rate (L/min) per filtration area of the filter.

The temperature of the washing solution used in the washing step is preferably 0° C. to 50° C.

The washing step may be performed only once or performed twice or more.

It is preferable that all of the present supply method, the purification of the chemical liquid, and other additional steps, such as opening of a container, washing of a container and a device, storage of a solution, and analysis, be performed in a clean room. It is preferable that the clean room meet the clean room standard described in international organization for standardization (ISO) 14644-1. The clean room more preferably meets any of International Organization for Standardization (ISO) class 1, ISO class 2, ISO class 3, or ISO class 4, even more preferably meets ISO class 1 or ISO class 2, and particularly preferably meets ISO class 1.

[Use of Chemical Liquid]

The chemical liquid supplied by the present supply method is preferably used for manufacturing a semiconductor device. The chemical liquid can be used in any step for manufacturing a semiconductor device. For example, the chemical liquid can be used for a treatment using an organic substance in a wiring line forming process including photolithography (including a lithography step, an etching step, an ion implantation step, a peeling step, and the like). Examples of specific uses of the chemical liquid include a pre-wet liquid, a developer, a rinsing liquid, a stripper, a CMP slurry, and a post-CMP rinsing liquid (p-CMP rinsing liquid).

The chemical liquid may be used after being diluted with another organic solvent and/or a solvent such as water. In a case where the chemical liquid is used as a CMP slurry, for example, additives such as abrasive grains and an oxidant may be added to the chemical liquid. Furthermore, the chemical liquid can also be used as a solvent for diluting the CMP slurry.

The chemical liquid may be used for only one of the aforementioned uses, or may be used for two or more uses among the above.

[Pattern Forming Method]

It is preferable that the chemical liquid supplied by the present supply method be used as a treatment liquid in a pattern forming method having the following steps.

(A) A pre-wetting step of bringing a pre-wet liquid into contact with the surface of a substrate,

(B) a resist film forming step of forming a resist film on the substrate having undergone the pre-wetting step by using a resist composition,

(C) an exposure step of exposing the resist film,

(D) a development step of developing the exposed resist film by using a developer, and

(E) a rinsing step of bringing a rinsing liquid into contact with the substrate on which the resist pattern is formed.

A pattern forming method is more preferable which has the above steps (A) to (E) and uses the aforementioned chemical liquid as at least one liquid selected from the group consisting of the pre-wet liquid, developer, and rinsing liquid described above.

Hereinafter, each step included in the pattern forming method will be described.

<(A) Pre-Wetting Step>

The pre-wetting step is a step of bringing a pre-wet liquid into contact with the surface of a substrate.

As the substrate, known substrates used for manufacturing semiconductors can be used without particular limitation. Examples of the substrate include an inorganic substrate such as silicon, SiO₂, or SiN, a coating-type inorganic substrate such as Spin On Glass (SOG), and the like.

Furthermore, the substrate may be a substrate with an antireflection film comprising an antireflection film. As the antireflection film, a known organic or inorganic antireflection film can be used.

The method of bringing the pre-wet liquid into contact with the surface of a substrate is not particularly limited, and a known coating method can be used. Particularly, as the coating method, spin coating is preferable because this method makes it possible to form a uniform resist film by using smaller amounts of resist composition in the resist film forming step which will be described later.

The thickness of a pre-wet liquid layer formed on the substrate by using the pre-wet liquid is preferably 0.001 to 10 μm, and more preferably 0.005 to 5 μm.

(Pre-Wet Liquid)

As the pre-wet liquid, a pre-wet liquid containing an organic solvent is preferable. As the organic solvent contained in the pre-wet liquid, for example, at least one kind of organic solvent is preferable which is selected from the group consisting of a hydrocarbon-based solvent, a ketone-based solvent, an ester-based solvent, an alcohol-based solvent, an amide-based solvent, and an ether-based solvent, a hydrocarbon-based solvent, an ether-based solvent, or a ketone-based solvent is more preferable, and a hydrocarbon-based solvent or an ether-based solvent is even more preferable.

The chemical liquid supplied by the present supply method can be used as the aforementioned pre-wet liquid.

It is preferable that the surface tension of the pre-wet liquid be higher than the surface tension of the resist composition to be used for coating.

Generally, the pre-wet liquid is supplied to the wafer by a method of moving a prewet nozzle to a position above the central portion of the wafer. Then, by opening or closing a valve, the pre-wet liquid is supplied to the wafer.

In a state where the wafer stands still, a predetermined amount of the pre-wet liquid is supplied to the central portion of the wafer from the prewet nozzle. Then, the wafer is rotated at a first velocity V1 of, for example, about 500 rotations per minute (rpm) such that the pre-wet liquid on the wafer is diffused over the entire surface of the wafer, which makes the entire surface of the wafer wet with the pre-wet liquid.

The upper limit of the first velocity V1 is not particularly limited, but is preferably 3,000 rpm or less.

Thereafter, the valve of a line connected to a resist composition is opened. As a result, the resist composition starts to be jetted from a resist nozzle, and the resist composition starts to be supplied to the central portion of the wafer.

The resist composition may be a resist composition for ArF exposure, a resist composition for EUV exposure, or a resist composition for KrF exposure. That is, the pre-wet liquid may be a pre-wet liquid that is used by being applied to a substrate to be coated with a resist composition for ArF exposure is applied, a pre-wet liquid that is used by being applied to a substrate to be coated with a resist composition for EUV exposure, or a pre-wet liquid that is used by being applied to a substrate to be coated with a resist composition for KrF exposure.

In this way, (B) resist film forming step (described later) is started. In the resist film forming step, from the first velocity V1, the rotation speed of the wafer is increased to a second velocity V2 of about 2,000 to 4,000 rpm, for example. The wafer rotating at the first velocity V1 before the start of the resist film forming step is then gradually accelerated such that the speed continuously and smoothly changes. At this time, the acceleration of the rotation of the wafer is gradually increased from zero, for example. In order to finish the resist film forming step, the acceleration of the rotation of the wafer is reduced such that the rotation speed of the wafer smoothly reaches the second velocity V2. In this way, during the resist film forming step, the rotation speed of the wafer changes such that the transition from the first velocity V1 to the second velocity V2 is represented by an S-shaped curve. In the resist film forming step, due to the centrifugal force, the resist composition supplied to the central portion of the wafer spreads over the entire surface of the wafer, whereby the surface of the wafer is coated with the resist composition.

The technique for saving resist by changing the rotation speed of a wafer at the time of resist coating is specifically described in JP2009-279476A.

The interval between a point in time when (A) pre-wetting step has finished and a point in time when resist composition coating in (B) resist film forming step is started is not particularly limited, but is preferably 7 seconds or less.

The pre-wet liquid may be recycled. That is, the pre-wet liquid used in the pre-wetting step can be recovered and used in the pre-wetting step for other wafers.

In a case where the pre-wet liquid is recycled, it is preferable to adjust the content of the impurity metal, organic impurity, water, and the like contained in the recovered pre-wet liquid. The adjustment method is as described above as the manufacturing method of the pre-wet liquid.

<(B) Resist Film Forming Step>

The resist film forming step is a step of forming a resist film on the substrate having undergone the pre-wetting step by using a resist composition (preferably, by coating the substrate with a resist composition).

The substrate having undergone the pre-wetting step is a substrate comprising a pre-wet liquid layer, and is also called a pre-wetted substrate.

Hereinafter, first, the form of the resist composition will be described.

<Resist Composition>

The resist composition that can be used in the resist film forming step is not particularly limited, and a known resist composition can be used.

The resist composition may be, for example, for positive tone development or negative tone development. The light for exposure of the resist film formed of the resist composition is not limited. For example, the resist composition may be a resist composition for ArF exposure, a resist composition for EUV exposure, or a resist composition for KrF exposure.

It is preferable that the resist composition contain a resin which contains a repeating unit containing a group generating a polar group (such as a carboxyl group or a phenolic hydroxyl group) by being decomposed by the action of an acid (hereinafter, the resin will be also called “acid-decomposable resin” in the present specification) and a compound which generates an acid by the irradiation with actinic rays or radiation (hereinafter, the compound will be also called “photoacid generator” in the present specification).

Particularly, the following resist compositions are preferable.
Resist composition containing resin represented by Formula (I) which will be described later
Resist composition containing acid-decomposable resin having phenolic hydroxyl group which will be described later
Resist composition containing hydrophobic resin, which will be described later, and acid-decomposable resin

Hereinafter, each of the components of the resist compositions will be described.

(Acid-Decomposable Resin)

In the acid-decomposable group, the polar group is protected with a group dissociated by an acid (acid-dissociable group). Examples of the acid-dissociable group include —C(R₃₆)(R₃₇)(R₃₈), —C(R₃₆)(R₃₇)(OR₃₉), —C(R₀₁)(R₀₂)(OR₃₉), and the like.

In the Formulas, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

Examples of the acid-decomposable resin include a resin P having an acid-decomposable group represented by Formula (AI).

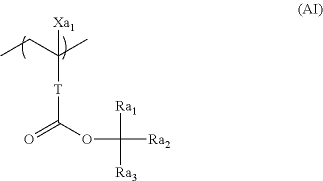

In Formula (AI),

Xa₁ represents a hydrogen atom or an alkyl group which may have a substituent.

represents a single bond or a divalent linking group.

Ra₁ to Ra₃ each independently represent an alkyl group (linear or branched) or a cycloalkyl group (monocyclic or polycyclic).

Two out of Ra₁ to Ra₃ may be bonded to each other to form a cycloalkyl group (monocyclic or polycyclic).

Examples of the alkyl group which is represented by Xa₁ and may have a substituent include a methyl group and a group represented by —CH₂—R₁₁. R₁₁ represents a halogen atom (such as a fluorine atom), a hydroxyl group, or a monovalent organic group.

Xa₁ is preferably a hydrogen atom, a methyl group, a trifluoromethyl group, or a hydroxymethyl group.

Examples of the divalent linking group represented by T include an alkylene group, a —COO-Rt- group, a —O—Rt- group, and the like. In the Formulas, Rt represents an alkylene group or a cycloalkylene group.

T is preferably a single bond or a —COO—Rt- group. Rt is preferably an alkylene group having 1 to 5 carbon atoms, and more preferably a —CH₂— group, a —(CH₂)₂— group, or a —(CH₂)₃— group.

The alkyl group represented by Rₐ₁ to Rₐ₃ preferably has 1 to 4 carbon atoms.

The cycloalkyl group represented by Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

The cycloalkyl group formed by the bonding of two groups out of Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group. The cycloalkyl group is more preferably a monocyclic cycloalkyl group having 5 or 6 carbon atoms.

In the cycloalkyl group formed by the bonding of two groups out of Ra₁ to Ra₃, for example, one methylene group constituting the ring may be substituted with a heteroatom such as an oxygen atom or a group having a heteroatom such as a carbonyl group.

As the repeating unit represented by Formula (AI), for example, an aspect is preferable in which Ra₁ is a methyl group or an ethyl group, and Ra₂ and Ra₃ are bonded to each other to form the aforementioned cycloalkyl group.

Each of the above groups may have a substituent. Examples of the substituent include an alkyl group (having 1 to 4 carbon atoms), a halogen atom, a hydroxyl group, an alkoxy group (having 1 to 4 carbon atoms), a carboxy group, an alkoxycarbonyl group (having 2 to 6 carbon atoms), and the like. The number of carbon atoms in the substituent is preferably equal to or smaller than 8.

The total content of the repeating unit represented by Formula (AI) with respect to all the repeating units in the resin P is preferably 20 to 90 mol %, more preferably 25 to 85 mol %, and even more preferably 30 to 80 mol %.

Specific examples of the repeating unit represented by Formula (AI) will be shown below, but the present invention is not limited thereto.

In the specific examples, Rx and Xa₁ each independently represent a hydrogen atom, CH₃, CF₃, or CH₂OH. Rxa and Rxb each represent an alkyl group having 1 to 4 carbon atoms. Z represents a substituent containing a polar group. In a case where there is a plurality of Z's, Z's are independent from each other. p represents 0 or a positive integer. Examples of the substituent represented by Z containing a polar group include a hydroxyl group, a cyano group, an amino group, an alkylamide group, a sulfonamide group, and a linear or branched alkyl group or cycloalkyl group having these groups.

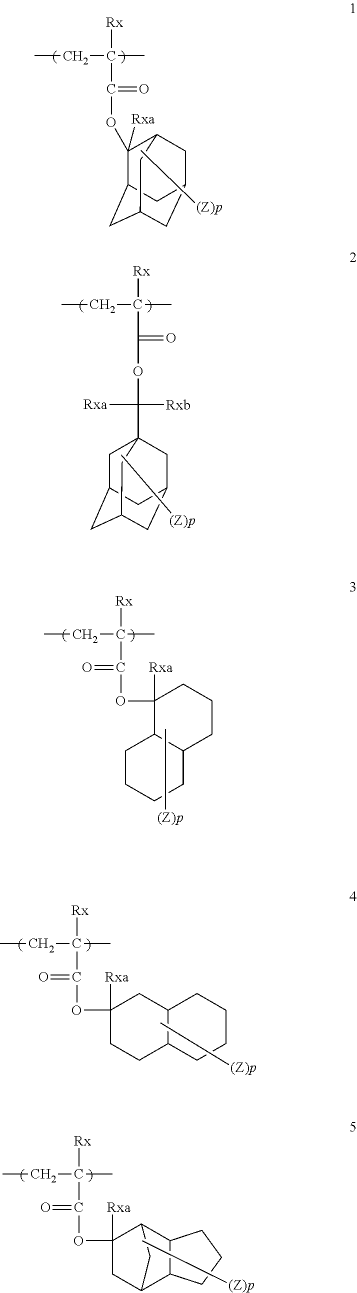

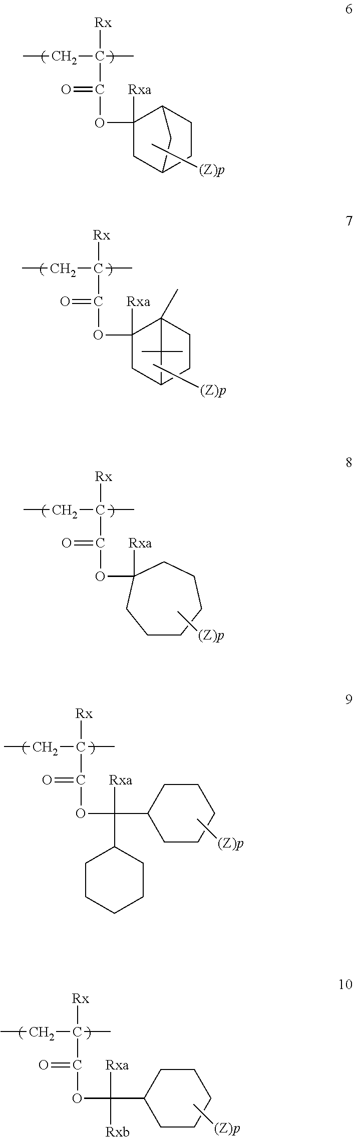

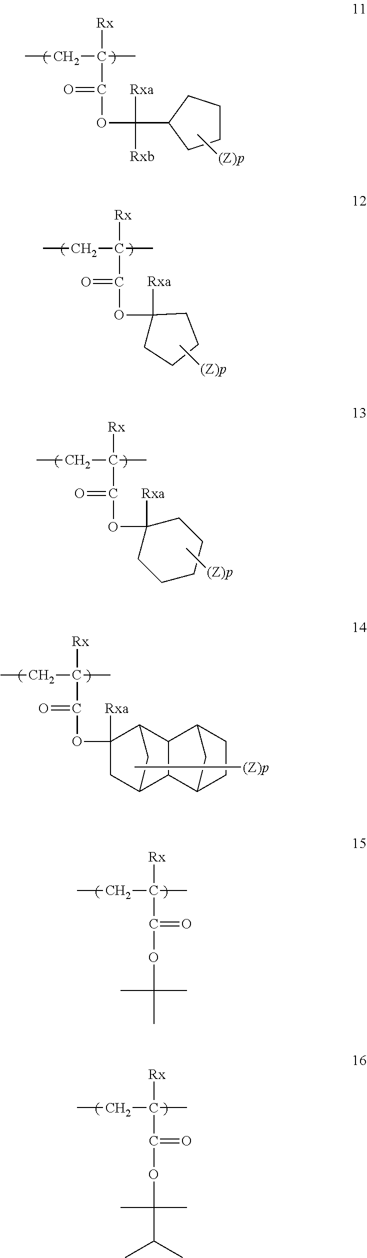

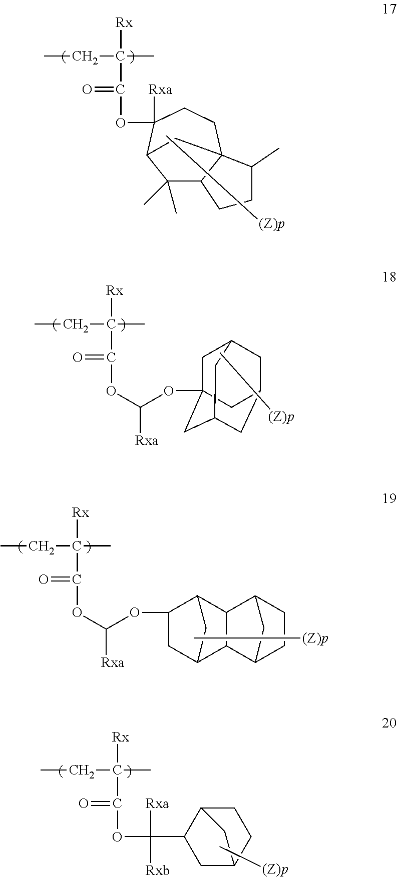

(Repeating Unit Having Lactone Structure)

It is preferable that the resin P contain a repeating unit Q having a lactone structure.

The repeating unit Q having a lactone structure preferably has a lactone structure on a side chain. For example, the repeating unit Q is more preferably a repeating unit derived from a (meth)acrylic acid derivative monomer.

One kind of repeating unit Q having a lactone structure may be used singly, or two or more kinds of repeating units Q may be used in combination. It is preferable to use one kind of repeating unit Q.

The content of the repeating unit Q having a lactone structure with respect to all the repeating units in the resin P is, for example, 3 to 80 mol %, and preferably 3 to 60 mol %.

The lactone structure is preferably a 5- to 7-membered lactone structure, and more preferably a structure in which another ring structure is fused with a 5- to 7-membered lactone structure by forming a bicyclo structure or a spiro structure.

It is preferable that the lactone structure have a repeating unit having a lactone structure represented by any of Formulas (LC1-1) to (LC1-17). As the lactone structure, a lactone structure represented by Formula (LC1-1), Formula (LC1-4), Formula (LC1-5), or Formula (LC1-8) is more preferable, and a lactone structure represented by Formula (LC1-4) is even more preferable.

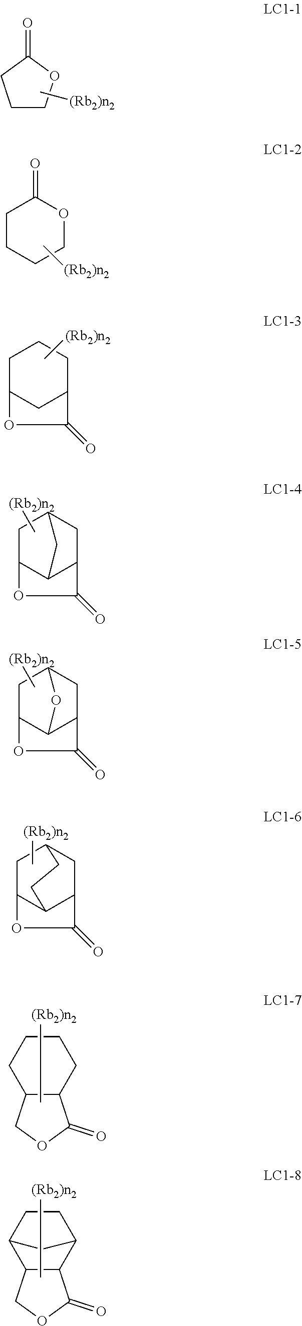

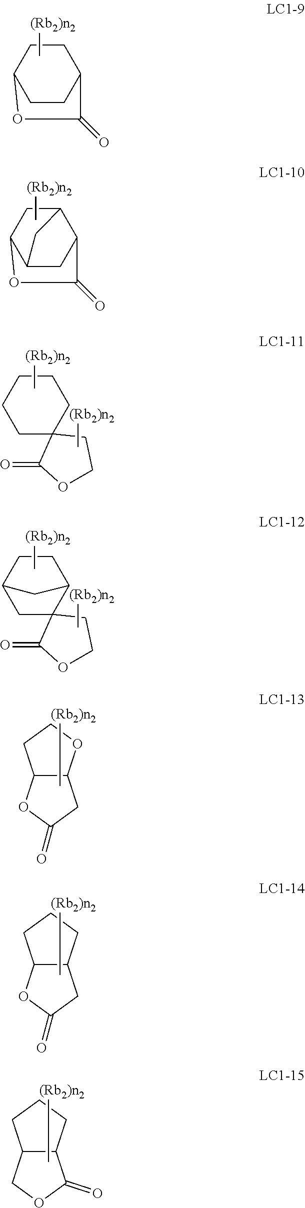

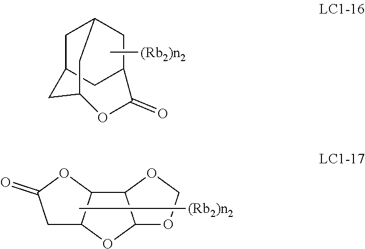

The lactone structure portion may have a substituent (Rb₂). As the substituent (Rb₂), for example, an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, and the like are preferable. n₂ represents an integer of 0 to 4. In a case where n₂ 2 or more, a plurality of substituents (Rb₂) may be the same as or different from each other, and a plurality of substituents (Rb₂) may be bonded to each other to form a ring.

The resin P is preferably a resin including a repeating unit selected from the group consisting of a repeating unit represented by Formula (a), a repeating unit represented by Formula (b), a repeating unit represented by Formula (c), a repeating unit represented by Formula (d), and a repeating unit represented by Formula (e) (hereinafter, this resin will be referred to as “resin represented by Formula (I)” as well).

The resin represented by Formula (I) is a resin whose solubility in a developer, which contains an organic solvent as a main component, is reduced by the action of an acid. The resin contains an acid-decomposable group. In the pre-wet liquid, the resin represented by Formula (I) is excellently dissolved. Therefore, the pre-wet liquid makes it easy to obtain a uniform resist film by using smaller amounts of the resist composition. Hereinafter, the resin represented by Formula (I) will be described.

The resin represented by the Formula (I) may be a resin that substantially consists of only the repeating units represented by Formulas (a) to (e). For example, in the resin represented by Formula (I), the content of repeating units other than the repeating units represented by Formulas (a) to (e) may be in a range of 0 to 5 mol % (more preferably in a range of 0 to 1 mol %) with respect to all the repeating units of the resin.

Resin Represented by Formula (I)

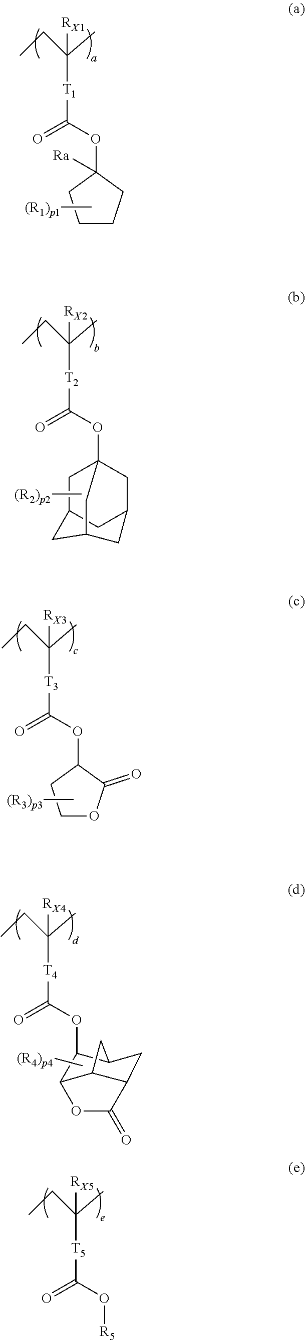

Formula (I) is constituted with a repeating unit (a) (repeating unit represented by Formula (a)), a repeating unit (b) (repeating unit represented by Formula (b)), a repeating unit (c) (repeating unit represented by Formula (c)), a repeating unit (d) (repeating unit represented by Formula (d)), and a repeating unit (e) (repeating unit represented by Formula (e)).

Rₓ₁ to Rₓ₅ each independently represent a hydrogen atom or an alkyl group which may have a substituent.

R₁ to R₄ each independently represent a monovalent substituent, and p₁ to p₄ each independently represent 0 or a positive integer.

Rₐ represents a linear or branched alkyl group.

T₁ to T₅ each independently represent a single bond or a divalent linking group.

R₅ represents a monovalent organic group.

a to e each represent mol % (mol % of each repeating unit with respect to a total of 100 mol % of the repeating units (a) to (e)). a to e each independently represent a number included in ranges of 0≤a≤100, 0≤b≤100, 0≤c≤100, 0≤d≤100, and 0≤e≤100. Here, a+b+c+d+e=100, and a+b≠0.

In Formula (I), the repeating unit (e) has a structure different from all of the repeating units (a) to (d).

Examples of the alkyl group represented by Rₓ₁ to Rₓ₅ that may contain a substituent include a methyl group and a group represented by —CH₂—R₁₁. R₁₁ represents a halogen atom (such as a fluorine atom), a hydroxyl group, or a monovalent organic group.

Rₓ₁ to Rₓ₅ preferably each independently represent a hydrogen atom, a methyl group, a trifluoromethyl group, or a hydroxymethyl group.

Examples of the divalent linking group represented by T₁ to T₅ in Formula (I) include an alkylene group, a —COO—Rt- group, a —O—Rt- group, and the like. In the Formulas, Rt represents an alkylene group or a cycloalkylene group.

T₁ to T₅ preferably each independently represent a single bond or a —COO—Rt- group. Rt is preferably an alkylene group having 1 to 5 carbon atoms, and more preferably a —CH₂— group, a —(CH₂)₂— group, or a —(CH₂)₃— group.

In Formula (I), Rₐ represents a linear or branched alkyl group. Examples thereof include a methyl group, an ethyl group, a t-butyl group, and the like. Among these, a linear or branched alkyl group having 1 to 4 carbon atoms is preferable.

In Formula (I), R₁ to R₄ each independently represent a monovalent substituent. R₁ to R₄ are not particularly limited, and examples thereof include a hydroxyl group, a cyano group, and a linear or branched alkyl or cycloalkyl group having a hydroxyl group, a cyano group, and the like.

In Formula (I), p₁ to p₄ each independently represent 0 or a positive integer. The upper limit of p₁ to p₄ equals the number of hydrogen atoms which can be substituted in each repeating unit.

In formula (I), R₅ represents a monovalent organic group. R₅ is not particularly limited, and examples thereof include a monovalent organic group having a sultone structure, a monovalent organic group having a cyclic ether such as tetrahydrofuran, dioxane, 1,4-thioxane, dioxolane, and 2,4,6-trioxabicyclo[3.3.0]octane, and an acid-decomposable group (for example, an adamantyl group quaternized by the substitution of carbon at a position bonded to a —COO group with an alkyl group).

The repeating unit (b) in Formula (I) is preferably formed of the monomer described in paragraphs “0014” to “0018” of JP2016-138219A.

In Formula (I), a to e each represent mol % (mol % of each repeating unit with respect to a total of 100 mol % of the repeating units (a) to (e)). a to e each independently represent a number included in ranges of 0≤a≤100, 0≤b≤100, 0≤c<100, 0≤d<100, and 0≤e<100. Here, a+b+c+d+e=100, and a+b≠0.

In Formula (I), a+b is preferably 20 to 90 mol %, more preferably 25 to 85 mol %, and even more preferably 30 to 80 mol %.

In Formula (I), the content of the repeating unit having an acid-decomposable group with respect to all the repeating units is preferably 20 to 90 mol %, more preferably 25 to 85 mol %, and even more preferably 30 to 80 mol %.

Furthermore, in Formula (I), c+d (the content of the repeating unit having a lactone structure with respect to all the repeating units) is preferably 3 to 80 mol %, and more preferably 3 to 60 mol %.

One kind of each of the repeating unit (a) to repeating unit (e) may be used singly, or two or more kinds of each of the repeating unit (a) to repeating unit (e) may be used in combination. In a case where two or more kinds of repeating units are used in combination, the total content of each repeating unit is preferably within the above range.

The weight-average molecular weight (Mw) of the resin represented by Formula (I) is preferably 1,000 to 200,000 in general, more preferably 2,000 to 20,000, and even more preferably 3,000 to 15,000. The weight-average molecular weight is determined by Gel Permeation Chromatography (GPC) by using tetrahydrofuran (THF) as a developing solvent, and expressed in terms of polystyrene.

In the resist composition, the content of the resin represented by Formula (I) based on the total solid content of the resist composition is preferably 30% to 99% by mass in general, and more preferably 50% to 95% by mass.

(Repeating Unit Having Phenolic Hydroxyl Group)

The resin P may contain a repeating unit having a phenolic hydroxyl group.

Examples of the repeating unit having a phenolic hydroxyl group include a repeating unit represented by General Formula (I).

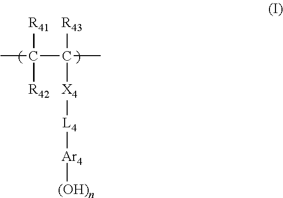

In the formula, R₄₁, R₄₂, and R₄₃ each independently represent a hydrogen atom, an alkyl group, a halogen atom, a cyano group, or an alkoxycarbonyl group. Here, R₄₂ and Ar₄ may be bonded to each other to form a ring. In this case, R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group. In a case where Ar₄ forms a ring by being bonded to R₄₂, Ar₄ represents an (n+2)-valent aromatic ring group.

n represents an integer of 1 to 5.

The alkyl group represented by R₄₁, R₄₂, and R₄₃ in General Formula (I) is preferably an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent, more preferably an alkyl group having 8 or less carbon atoms, and even more preferably an alkyl group having 3 or less carbon atoms.

The cycloalkyl group represented by R₄₁, R₄₂, and R₄₃ in General Formula (I) may be monocyclic or polycyclic. The cycloalkyl group is preferably a monocyclic cycloalkyl group having 3 to 8 carbon atoms such as a cyclopropyl group, a cyclopentyl group, or a cyclohexyl group which may have a substituent.

Examples of the halogen atom represented by R₄₁, R₄₂, and R₄₃ in General Formula (I) include a fluorine atom, a chlorine atom, a bromine atom, and an iodine atom. Among these, a fluorine atom is preferable.

As the alkyl group contained in the alkoxycarbonyl group represented by R₄₁, R₄₂, and R₄₃ in General Formula (I), the same alkyl group as the alkyl group represented by R₄₁, R₄₂, and R₄₃ described above is preferable.

Examples of the substituent in each of the above groups include an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, a cyano group, a nitro group, and the like. The number of carbon atoms in the substituent is preferably equal to or smaller than 8.

Ar₄ represents an (n+1)-valent aromatic ring group. Examples of a divalent aromatic ring group obtained in a case where n is 1 include an arylene group having 6 to 18 carbon atoms such as a phenylene group, a tolylene group, a naphthylene group, or an anthracenylene group which may have a substituent and an aromatic ring group containing a hetero ring such as thiophene, furan, pyrrole, benzothiophene, benzofuran, benzopyrrole, triazine, imidazole, benzimidazole, triazole, thiadiazole, or thiazole.

Specific examples of the (n+1)-valent aromatic ring group obtained in a case where n is an integer equal to or greater than 2 include groups obtained by removing (n−1) pieces of any hydrogen atoms from the specific examples of the divalent aromatic ring group described above.

The (n+1)-valent aromatic ring group may further have a substituent.

Examples of the substituent that the alkyl group, the cycloalkyl group, the alkoxycarbonyl group, the alkylene group, and the (n+1)-valent aromatic ring group described above can include the alkyl group exemplified as R₄₁, R₄₂, and R₄₃ in General Formula (I); an alkoxy group such as a methoxy group, an ethoxy group, a hydroxyethoxy group, a propoxy group, a hydroxypropoxy group, or a butoxy group; and an aryl group such as a phenyl group.

Examples of the alkyl group represented by R₆₄ in —CONR₆₄— (R₆₄ represents a hydrogen atom or an alkyl group) represented by X₄ include an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent. Among these, an alkyl group having 8 or less carbon atoms is preferable.

X₄ is preferably a single bond, —COO—, or —CONH—, and more preferably a single bond or —COO—.

The alkylene group represented by L₄ is preferably an alkylene group having 1 to 8 carbon atoms such as a methylene group, an ethylene group, a propylene group, a butylene group, a hexylene group, or an octylene group which may have a substituent.

Ar₄ is preferably an aromatic ring group having 6 to 18 carbon atoms that may have a substituent, and more preferably a benzene ring group, a naphthalene ring group, or a biphenylene ring group.

It is preferable that the repeating unit represented by General Formula (I) comprise a hydroxystyrene structure. That is, Ar₄ is preferably a benzene ring group.

The repeating unit having a phenolic hydroxyl group is preferably a repeating unit represented by General Formula (p1).

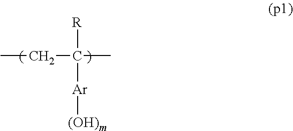

R in General Formula (p1) represents a hydrogen atom, a halogen atom, or a linear or branched alkyl group having 1 to 4 carbon atoms. A plurality of R's may be the same as or different from each other. As R in General Formula (p1), a hydrogen atom is preferable.

Ar in General Formula (p1) represents an aromatic ring, and examples thereof include an aromatic hydrocarbon ring having 6 to 18 carbon atoms that may have a substituent, such as a benzene ring, a naphthalene ring, an anthracene ring, a fluorene ring, or a phenanthrene ring, and an aromatic hetero ring containing a hetero ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, a benzene ring is preferable.

m in General Formula (p1) represents an integer of 1 to 5. m is preferably 1.

Specific examples of the repeating unit having a phenolic hydroxyl group will be shown below, but the repeating unit is not limited thereto. In the formulas, a represents 1 or 2.

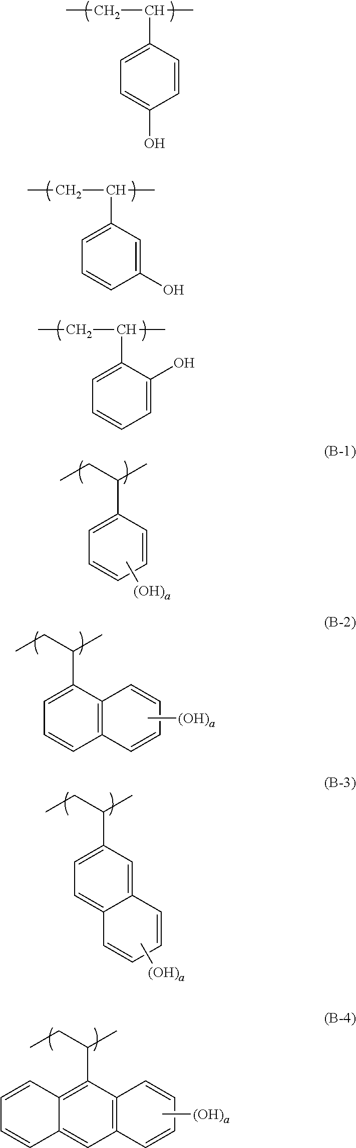

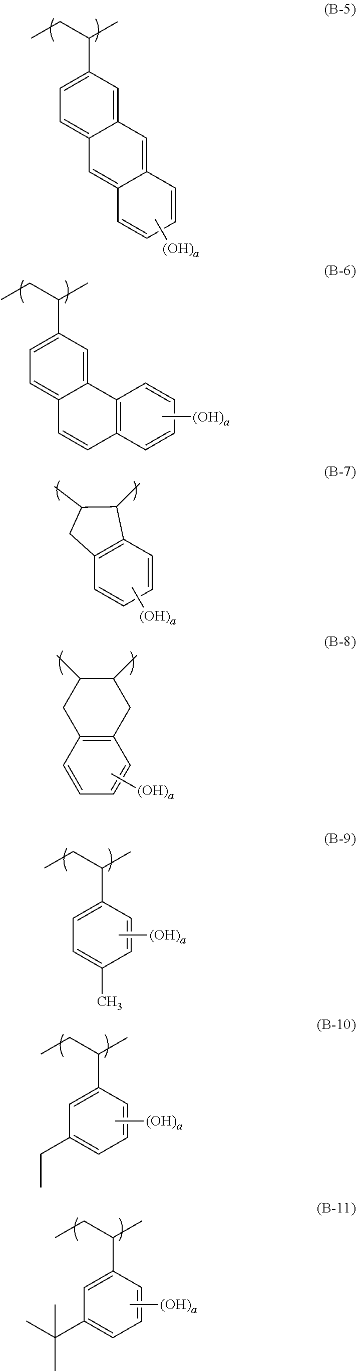

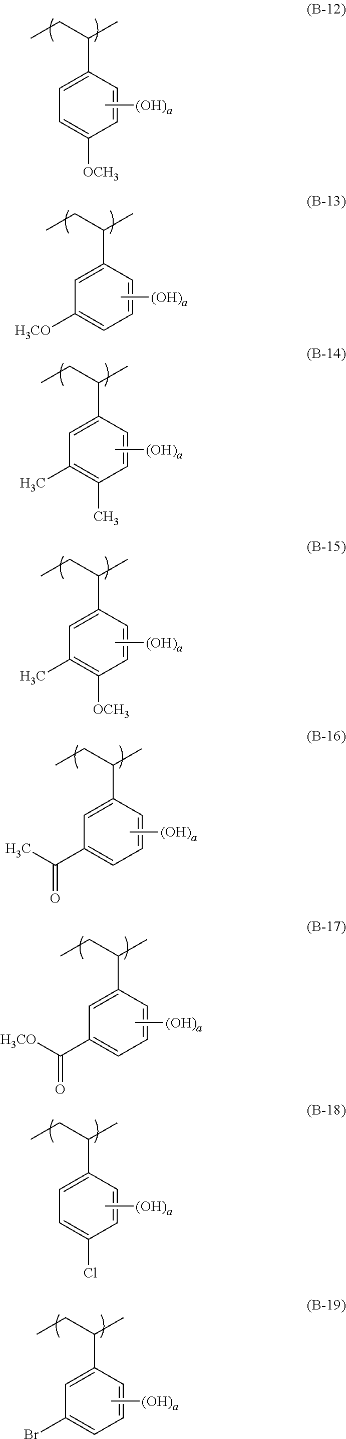

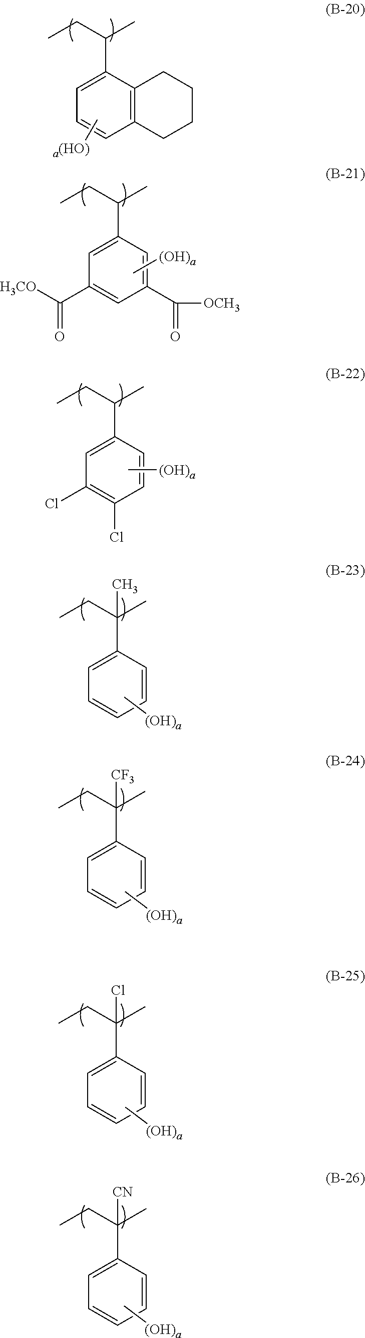

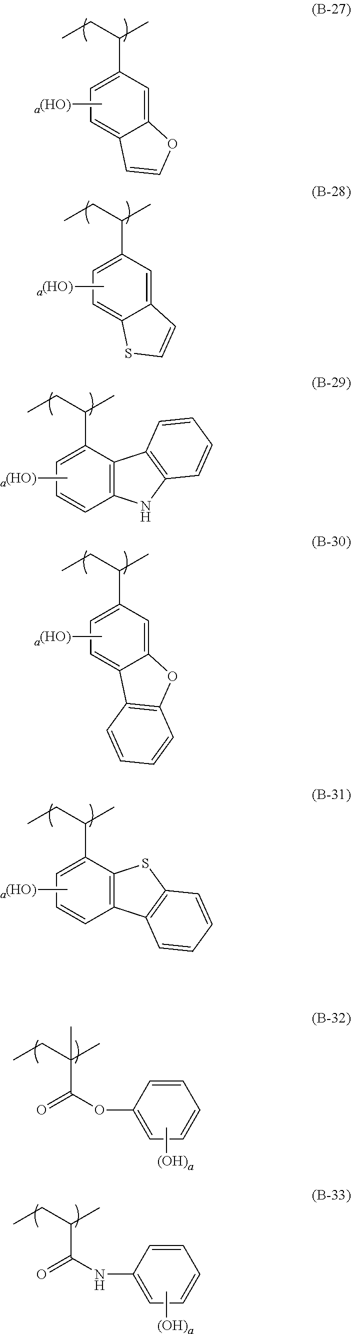

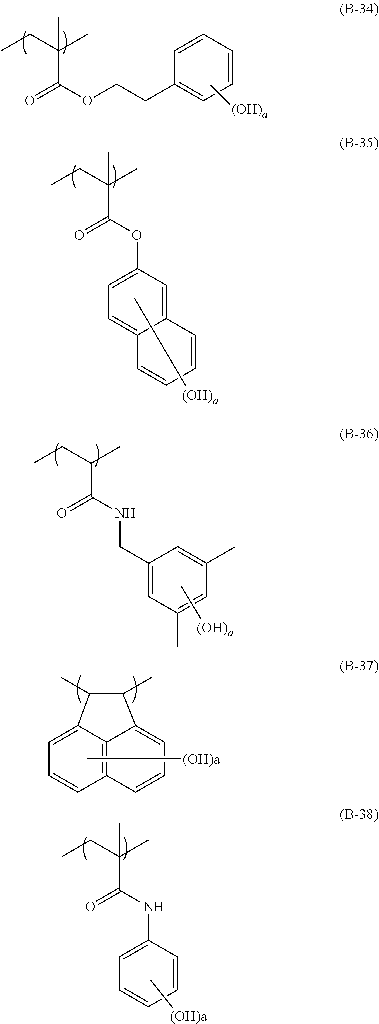

The content of the repeating unit having a phenolic hydroxyl group with respect to all the repeating units in the resin P is preferably 0 to 50 mol %, more preferably 0 to 45 mol %, and even more preferably 0 to 40 mol %.

(Repeating Unit Containing Organic Group Having Polar Group)

The resin P may further contain a repeating unit containing an organic group having a polar group, particularly, a repeating unit having an alicyclic hydrocarbon structure substituted with a polar group.

In a case where the resin (A) has such a repeating unit, the substrate adhesiveness and the affinity for a developer are improved. As the alicyclic hydrocarbon structure substituted with a polar group, an adamantyl group, a diamantyl group, or a norbornane group is preferable. As the polar group, a hydroxyl group or a cyano group is preferable.

Specific examples of the repeating unit having a polar group will be shown below, but the repeating unit is not limited thereto.

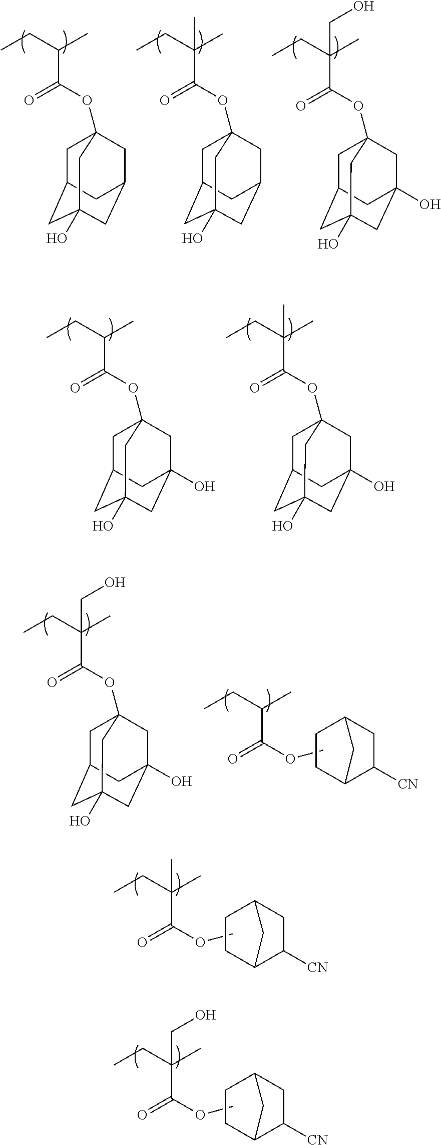

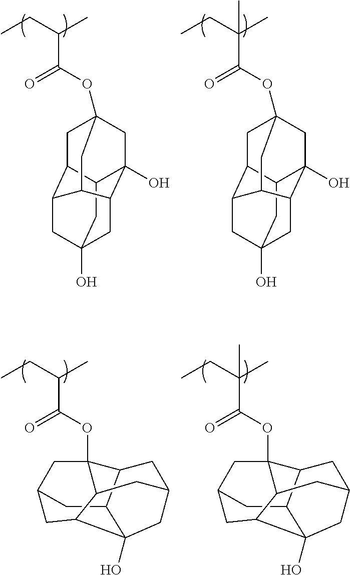

In a case where the resin P contains the repeating unit containing an organic group having a polar group, the content of the repeating unit with respect to all the repeating units in the resin P is preferably 1 to 50 mol %, more preferably 1 to 30 mol %, even more preferably 5 to 25 mol %, and particularly preferably 5 to 20 mol %.

(Repeating unit having group (photoacid generating group) generating acid by irradiation of actinic rays or radiation)

The resin P may contain a repeating unit having a group (photoacid generating group) generating an acid by the irradiation of actinic rays or radiation.

Examples of the repeating unit having a group (photoacid generating group) generating an acid by the irradiation of actinic rays or radiation include a repeating unit represented by Formula (4).

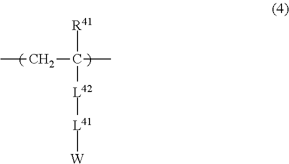

R⁴¹ represents a hydrogen atom or a methyl group. L⁴¹ represents a single bond or a divalent linking group. L⁴² represents a divalent linking group. W represents a structural moiety generating an acid on a side chain by being decomposed by the irradiation with actinic rays or radiation.

Specific examples of the repeating unit represented by Formula (4) will be shown below, but the present repeating unit is not limited thereto.

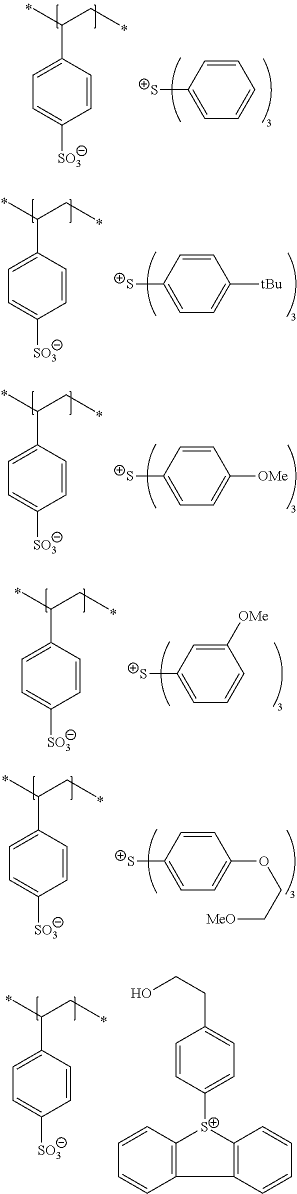

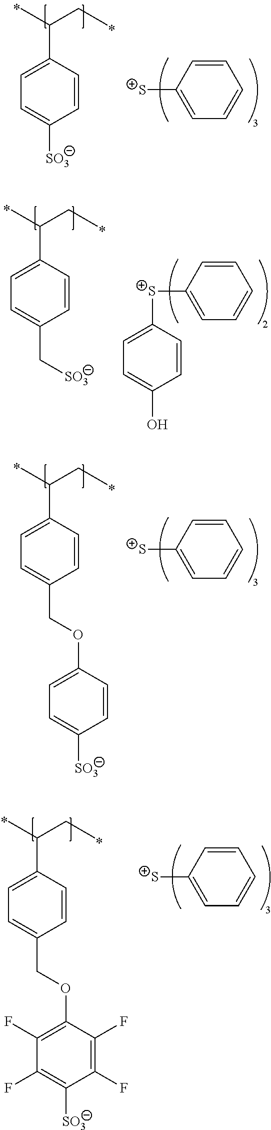

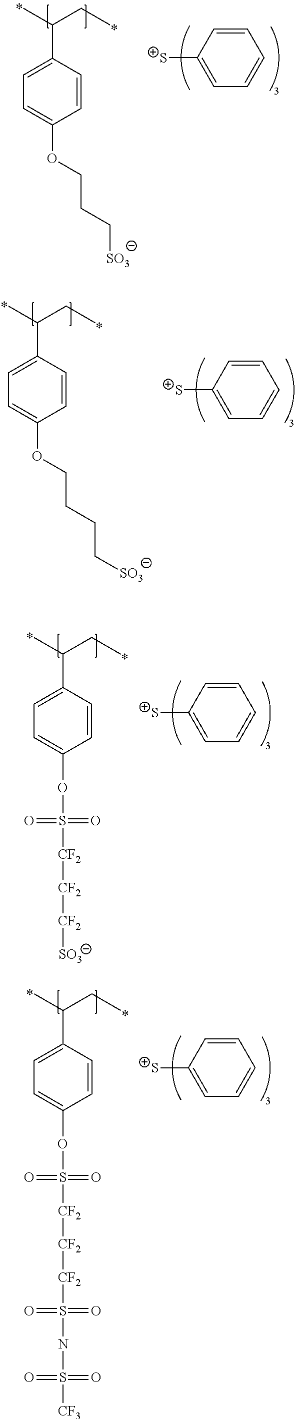

Examples of the repeating unit represented by Formula (4) also include the repeating units described in paragraphs “0094” to “0105” of JP2014-041327A.

In a case where the resin P contains the repeating unit having a photoacid generating group, the content of the repeating unit having a photoacid generating group with respect to all the repeating units in the resin P is preferably 1 to 40 mol %, more preferably 5 to 35 mol %, and even more preferably 5 to 30 mol %.

The resin P may contain a repeating unit represented by Formula (VI).

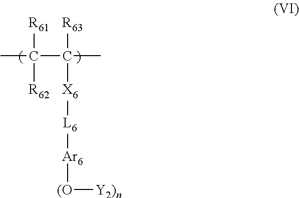

In Formula (VI), R₆₁, R₆₂, and R₆₃ each independently represent a hydrogen atom, an alkyl group, a cycloalkyl group, a halogen atom, a cyano group, or an alkoxycarbonyl group. Here, R₆₂ may be bonded to Ar₆ to form a ring, and in this case, R₆₂ represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1)-valent aromatic ring group. In a case where Ar₆ forms a ring by being bonded to R₆₂, Ar₆ represents an (n+2)-valent aromatic ring group.

In a case where n≥2, Y₂ each independently represent a hydrogen atom or a group which is dissociated by the action of an acid. Here, at least one of Y₂'s represents a group which is dissociated by the action of an acid.

n represents an integer of 1 to 4.

As the group Y₂ which is dissociated by the action of an acid, a structure represented by Formula (VI-A) is preferable.

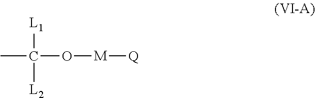

L₁ and L₂ each independently represent a hydrogen atom, an alkyl group, a cycloalkyl group, an aryl group, or a group obtained by combining an alkylene group and an aryl group.

M represents a single bond or a divalent linking group.

Q represents an alkyl group, a cycloalkyl group which may contain a heteroatom, an aryl group which may contain a heteroatom, an amino group, an ammonium group, a mercapto group, a cyano group, or an aldehyde group.

At least two out of Q, M, and Li may form a ring (preferably a 5- or 6-membered ring) by being bonded to each other.

The repeating unit represented by Formula (VI) is preferably a repeating unit represented by Formula (3).

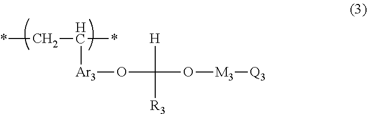

In Formula (3), Ar₃ represents an aromatic ring group.

R₃ represents a hydrogen atom, an alkyl group, a cycloalkyl group, an aryl group, an aralkyl group, an alkoxy group, an acyl group, or a heterocyclic group.

M₃ represents a single bond or a divalent linking group.

Q₃ represents an alkyl group, a cycloalkyl group, an aryl group, or a heterocyclic group.

At least two out of Q₃, M₃, and R₃ may form a ring by being bonded to each other.

The aromatic ring group represented by Ar₃ is the same as Ar₆ in Formula (VI) in a case where n in Formula (VI) is 1. Ar₃ is more preferably a phenylene group or a naphthylene group, and even more preferably a phenylene group.

Specific examples of the repeating unit represented by Formula (VI) will be shown below, but the repeating unit is not limited thereto.

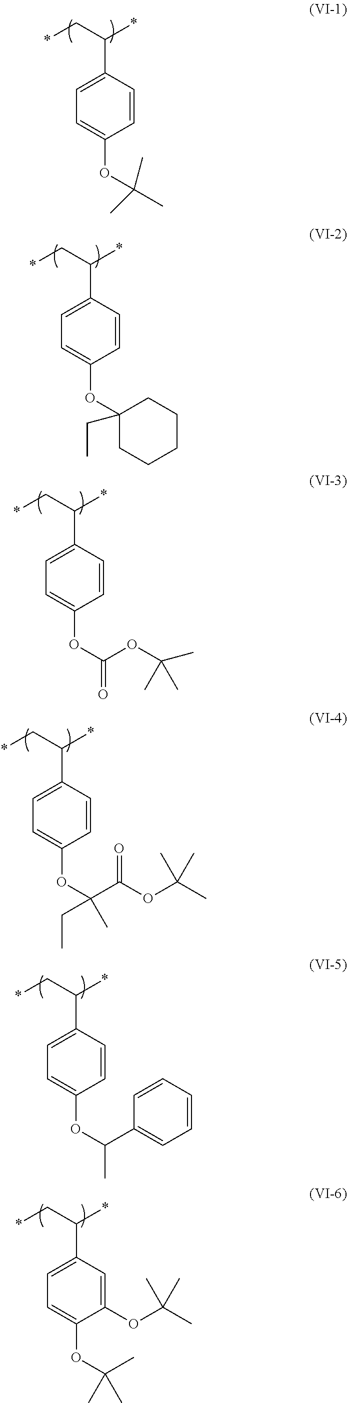

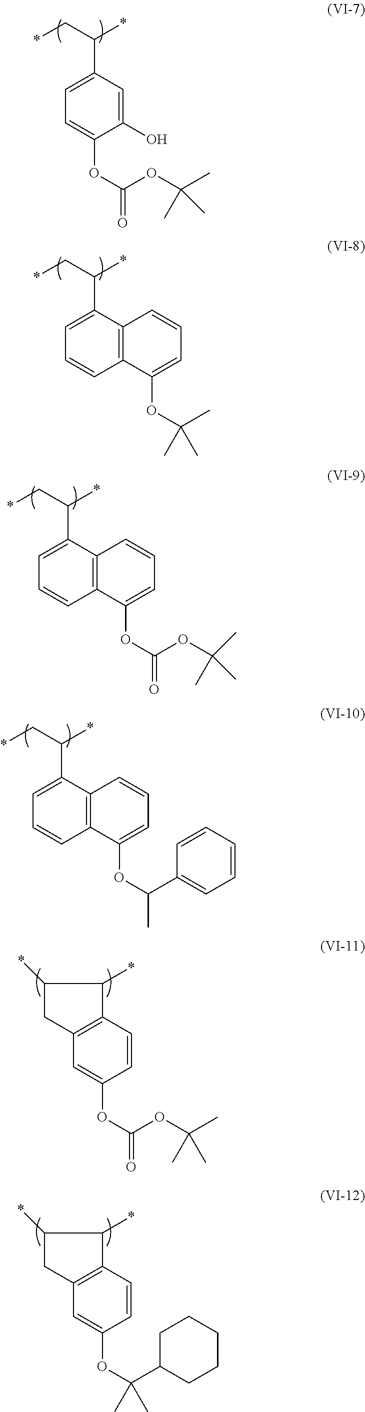

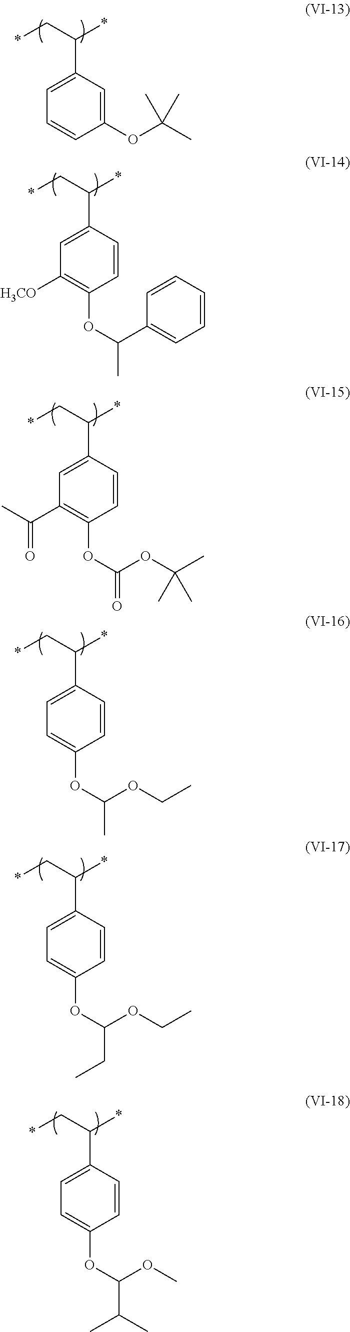

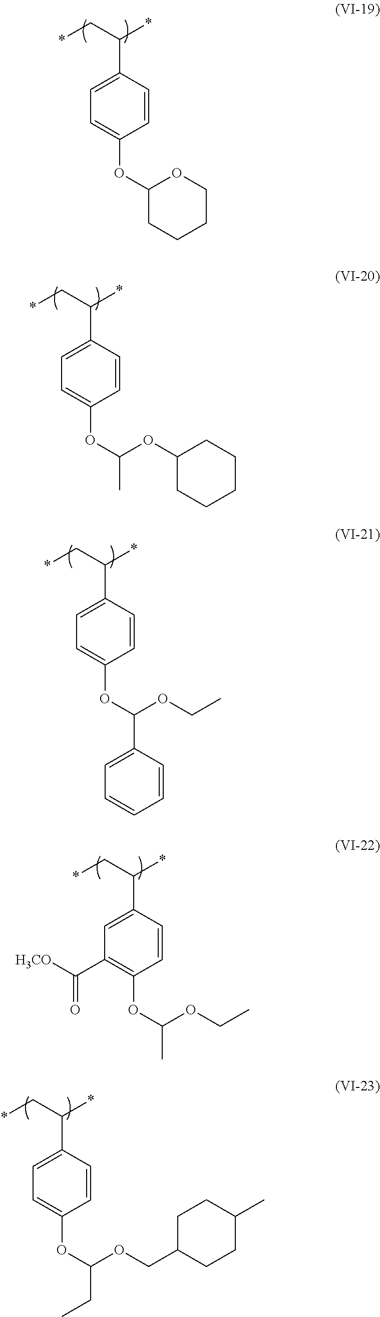

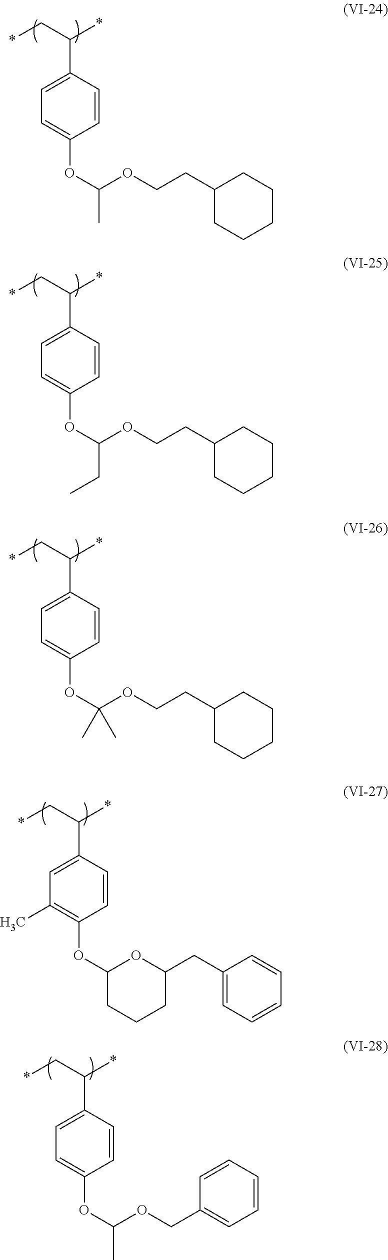

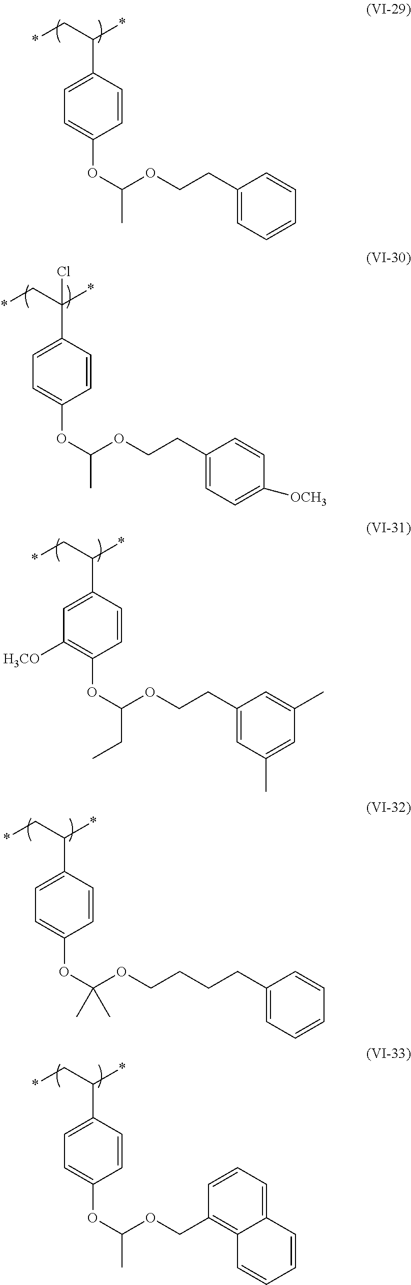

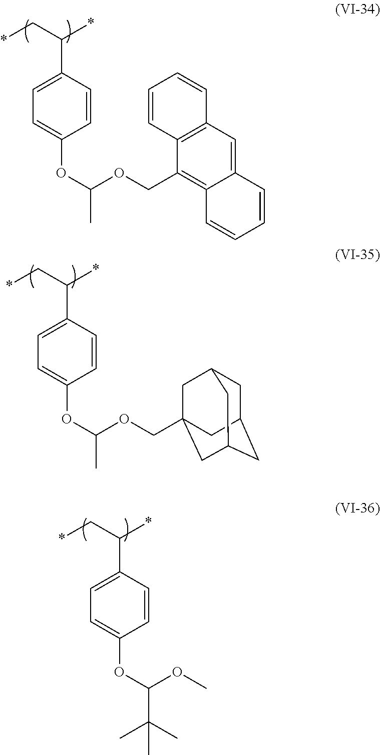

The resin P may contain a repeating unit represented by Formula (4).

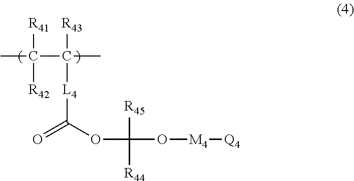

In Formula (4), R₄₁, R₄₂, and R₄₃ each independently represent a hydrogen atom, an alkyl group, a cycloalkyl group, a halogen atom, a cyano group, or an alkoxycarbonyl group. R₄₂ and L₄ may be bonded to each other to form a ring, and in this case, R₄₂ represents an alkylene group.

L₄ represents a single bond or a divalent linking group. In a case where L₄ forms a ring together with R₄₂, L₄ represents a trivalent linking group.

R₄₄ and R₄₅ each represent a hydrogen atom, an alkyl group, a cycloalkyl group, an aryl group, an aralkyl group, an alkoxy group, an acyl group, or a heterocyclic group.

M₄ represents a single bond or a divalent linking group.

Q₄ represents an alkyl group, a cycloalkyl group, an aryl group, or a heterocyclic group.

At least two out of Q₄, M₄, and R₄₄ may form a ring by being bonded to each other.

R₄₁, R₄₂, and R₄₃ have the same definition as R₄₁, R₄₂, and R₄₃ in Formula (IA), and the preferable range thereof is also the same.

L₄ has the same definition as T in Formula (AI), and the preferable range thereof is also the same.

R₄₄ and R₄₅ have the same definition as R₃ in Formula (3), and the preferable range thereof is also the same.

M₄ has the same definition as M₃ in Formula (3), and the preferable range thereof is also the same.

Q₄ has the same definition as Q₃ in Formula (3), and the preferable range thereof is also the same.

Examples of the ring formed by the bonding of at least two out of Q₄, M₄, and R₄₄ include a ring formed by the bonding of at least two out of Q₃, M₃, and R₃, and the preferable range thereof is also the same.

Specific examples of the repeating unit represented by Formula (4) will be shown below, but the repeating unit is not limited thereto.

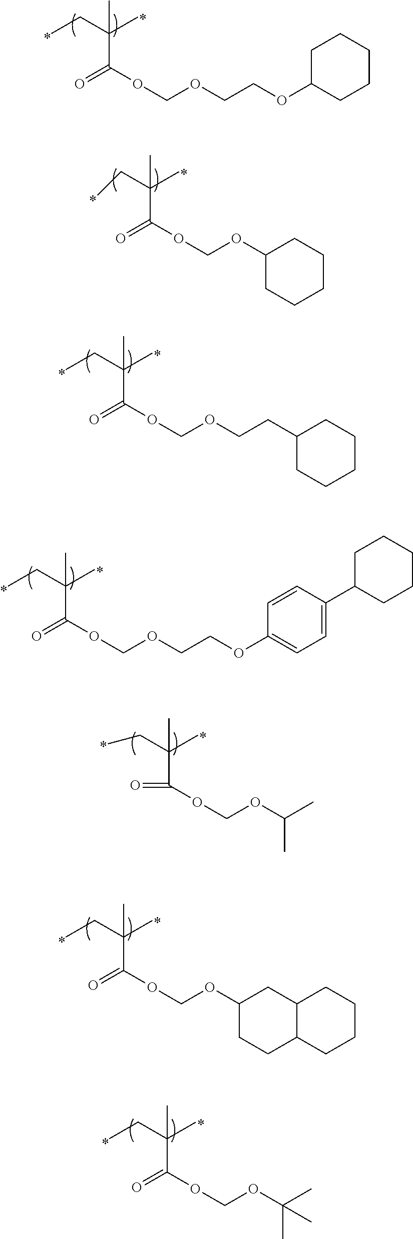

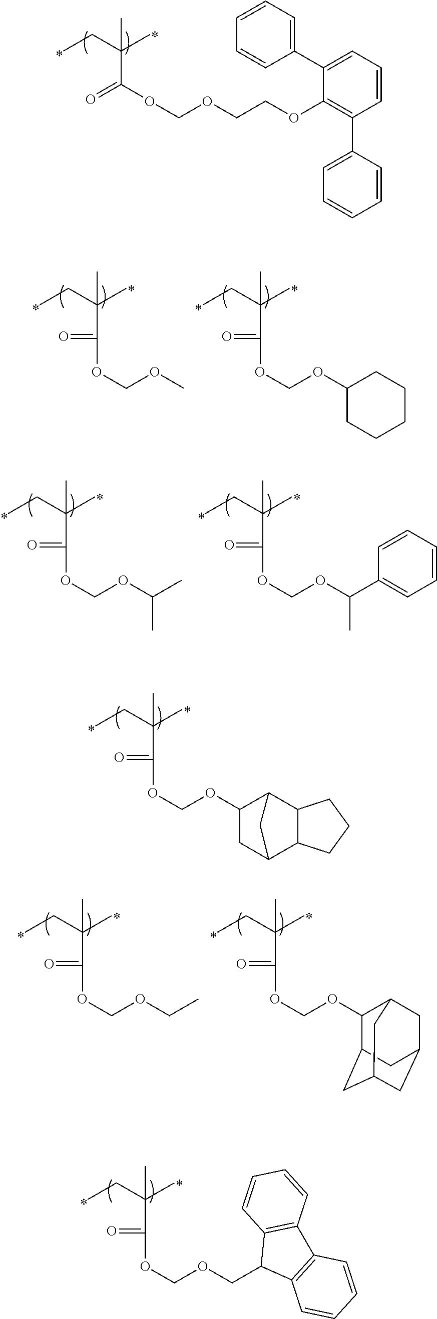

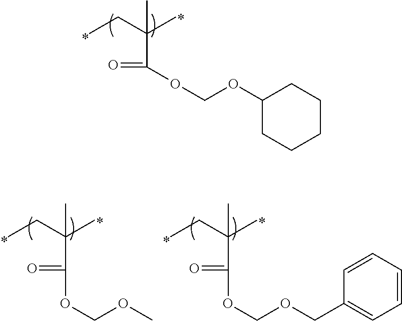

The resin P may contain a repeating unit represented by Formula (BZ).

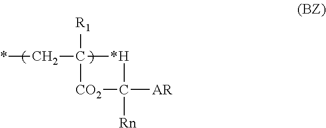

In Formula (BZ), AR represents an aryl group. Rn represents an alkyl group, a cycloalkyl group, or an aryl group. Rn and AR may be bonded to each other to form a nonaromatic ring.

R₁ represents a hydrogen atom, an alkyl group, a cycloalkyl group, a halogen atom, a cyano group, or an alkyloxycarbonyl group.

Specific examples of the repeating unit represented by Formula (BZ) will be shown below, but the repeating unit is not limited thereto.

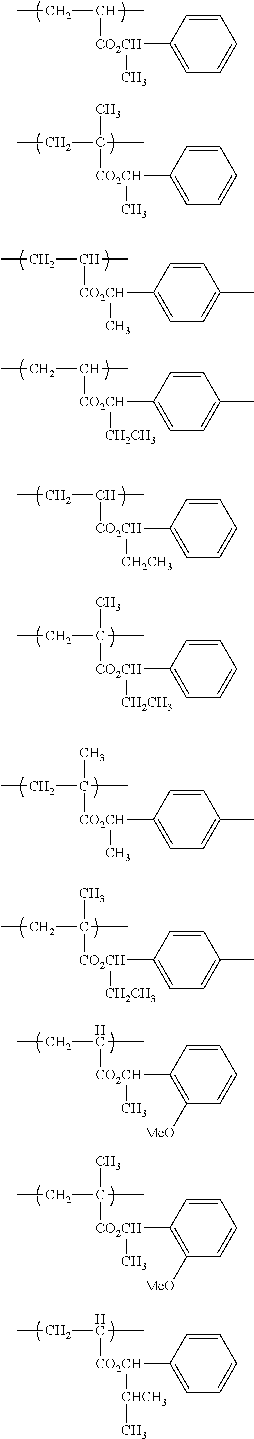

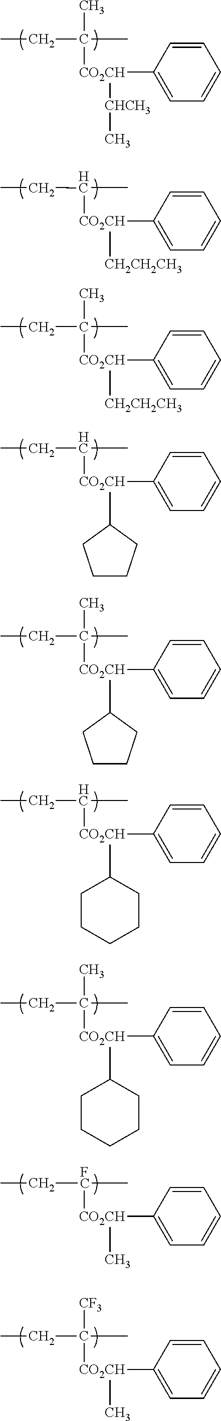

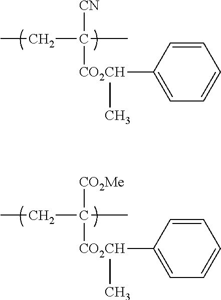

In the resin P, the content of the repeating unit having an acid-decomposable group (total content in a case where the resin P contains a plurality of kinds of the repeating units) with respect to all the repeating units in the resin P is preferably 5 to 80 mol %, more preferably 5 to 75 mol %, and even more preferably 10 to 65 mol %.

The resin P may contain a repeating unit represented by Formula (V) or Formula (VI).

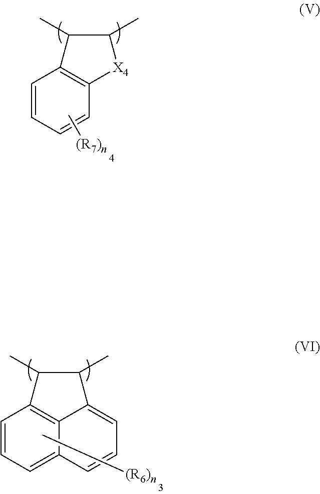

In the formula, R₆ and R₇ each independently represent a hydrogen atom, a hydroxy group, a linear, branched, and cyclic alkyl group having 1 to 10 carbon atoms, an alkoxy group, an acyloxy group, a cyano group, a nitro group, an amino group, a halogen atom, an ester group (—OCOR or —COOR: R represents an alkyl group having 1 to 6 carbon atoms or a fluorinated alkyl group), or a carboxyl group.

n₃ represents an integer of 0 to 6.

n₄ represents an integer of 0 to 4.

X⁴ represents a methylene group, an oxygen atom, or a sulfur atom.

Specific examples of the repeating unit represented by Formula (V) or Formula (VI) will be shown below, but the present invention is not limited thereto.

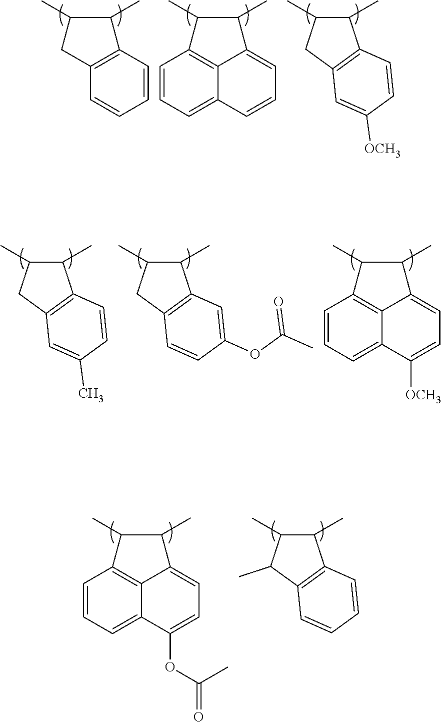

The resin P may further contain a repeating unit having a silicon atom on a side chain. Examples of the repeating unit having a silicon atom on a side chain include a (meth)acrylate-based repeating unit having a silicon atom, a vinyl-based repeating unit having a silicon atom, and the like. Typically, the repeating unit having a silicon atom on a side chain is a repeating unit having a silicon atom-containing group on a side chain. Examples of the silicon atom-containing group include a trimethylsilyl group, a triethylsilyl group, a triphenylsilyl group, a tricyclohexylsilyl group, a tristrimethylsiloxysilyl group, a tristrimethylsilyl silyl group, a methyl bistrimethylsilyl silyl group, a methyl bistrimethylsiloxysilyl group, a dimethyltrimethylsilyl silyl group, a dimethyl trimethylsiloxysilyl group, cyclic or linear polysiloxane shown below, a cage-like, ladder-like, or random silsesquioxane structure, and the like. In the Formulas, R and R′ each independently represent a monovalent substituent. * represents a bonding site.

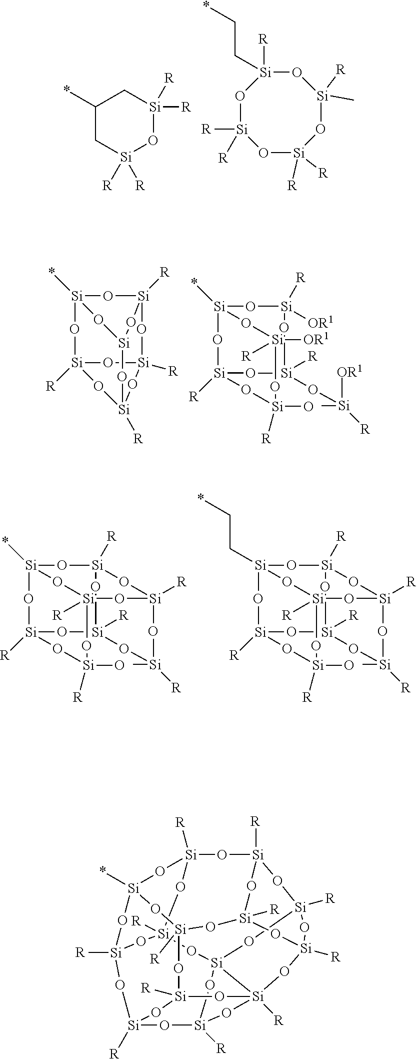

As the repeating unit having the aforementioned group, for example, a repeating unit derived from an acrylate or methacrylate compound having the aforementioned group or a repeating unit derived from a compound having the aforementioned group and a vinyl group is preferable.

It is preferable that the repeating unit having a silicon atom is preferably a repeating unit having a silsesquioxane structure. In a case where the repeating unit has a silsesquioxane structure, in forming an ultrafine pattern (for example, a line width equal to or smaller than 50 nm) having a cross-sectional shape with a high aspect ratio (for example, film thickness/line width is equal to or greater than 3), an extremely excellent collapse performance can be demonstrated.

Examples of the silsesquioxane structure include a cage-like silsesquioxane structure, a ladder-like silsesquioxane structure, and a random silsesquioxane structure. Among these, a cage-like silsesquioxane structure is preferable.

The cage-like silsesquioxane structure is a silsesquioxane structure having a cage-like skeleton. The cage-like silsesquioxane structure may be a complete cage-like silsesquioxane structure or an incomplete cage-like silsesquioxane structure, but is preferably a complete cage-like silsesquioxane structure.

The ladder-like silsesquioxane structure is a silsesquioxane structure having a ladder-like skeleton.

The random silsesquioxane structure is a silsesquioxane structure having a random skeleton.

The cage-like silsesquioxane structure is preferably a siloxane structure represented by Formula (S).

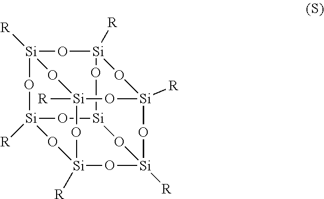

In Formula (S), R represents a monovalent organic group. A plurality of R's may be the same as or different from each other.

The organic group is not particularly limited, and specific examples thereof include a hydroxy group, a nitro group, a carboxy group, an alkoxy group, an amino group, a mercapto group, a blocked mercapto group (for example, a mercapto group blocked (protected) by an acyl group), an acyl group, an imide group, a phosphino group, a phosphinyl group, a silyl group, a vinyl group, a hydrocarbon group which may have a heteroatom, a (meth)acryl group-containing group, an epoxy group-containing group, and the like.

Examples of the heteroatom in the hydrocarbon group which may have a heteroatom include an oxygen atom, a nitrogen atom, a sulfur atom, a phosphorus atom, and the like.

Examples of the hydrocarbon group which may have a heteroatom include an aliphatic hydrocarbon group, an aromatic hydrocarbon group, a group obtained by combining these, and the like.

The aliphatic hydrocarbon group may be any of a linear, branched, or cyclic aliphatic hydrocarbon group. Specific examples of the aliphatic hydrocarbon group include a linear or branched alkyl group (particularly having 1 to 30 carbon atoms), a linear or branched alkenyl group (particularly having 2 to 30 carbon atoms), a linear or branched alkynyl group (particularly having 2 to 30 carbon atoms), and the like.

Examples of the aromatic hydrocarbon group include an aromatic hydrocarbon group having 6 to 18 carbon atoms such as a phenyl group, a tolyl group, a xylyl group, or a naphthyl group.

In a case where the resin P has the repeating unit having a silicon atom on a side chain, the content of the repeating unit with respect to all the repeating units in the resin P is preferably 1 to 30 mol %, more preferably 5 to 25 mol %, and even more preferably 5 to 20 mol %.

The weight-average molecular weight of the resin P that is measured by gel permeation chromatography (GPC) and expressed in terms of polystyrene is preferably 1,000 to 200,000, more preferably 3,000 to 20,000, and even more preferably 5,000 to 15,000. In a case where the weight-average molecular weight is 1,000 to 200,000, it is possible to prevent the deterioration of heat resistance and dry etching resistance, to prevent the deterioration of developability, and to prevent film forming properties from deteriorating due to the increase in viscosity.

The dispersity (molecular weight distribution) is generally 1 to 5, preferably 1 to 3, more preferably 1.2 to 3.0, and even more preferably 1.2 to 2.0.

The content of the resin P in the total solid content of the resist composition is preferably 50% to 99.9% by mass, and more preferably 60% to 99.0% by mass.

In the resist composition, one kind of resin P may be used singly, or two or more kinds of resins P may be used in combination.

(Photoacid Generator)

It is preferable that the resist composition contain a photoacid generator. As the photoacid generator, known photoacid generators can be used without particular limitation.

The content of the photoacid generator in the resist composition is not particularly limited. The content of the photoacid generator with respect to the total solid content of the resist composition is preferably 0.1% to 20% by mass, and more preferably 0.5% to 20% by mass. One kind of photoacid generator may be used singly, or two or more kinds of photoacid generators may be used in combination. In a case where two or more kinds of photoacid generators are used in combination, the total content thereof is preferably within the above range.

Examples of the photoacid generator include the compounds described in JP2016-057614A, JP2014-219664A, JP2016-138219A, and JP2015-135379A.

(Quencher)

The resist composition may contain a quencher (acid diffusion control agent). As the quencher, known quenchers can be used without particular limitation.

The quencher is, for example, a basic compound and has a function of inhibiting the acid-decomposable resin from being unintentionally decomposed in an unexposed area by the acid spread from an exposed area.

The content of the quencher in the resist composition is not particularly limited. The content of the quencher with respect to the total solid content of the resist composition is preferably 0.1% to 15% by mass, and more preferably 0.5% to 8% by mass with. One kind of quencher may be used singly, or two or more kinds of quenchers may be used in combination. In a case where two or more kinds of quenchers are used in combination, the total content thereof is preferably within the above range.

Examples of the quencher include the compounds described in JP2016-057614A, JP2014-219664A, JP2016-138219A, and JP2015-135379A.

(Hydrophobic Resin)

The resist composition may contain a hydrophobic resin.

It is preferable to design the hydrophobic resin such that the resin is localized within the surface of a resist film. However, unlike a surfactant, the hydrophobic resin does not need to have a hydrophilic group in a molecule and may not make a contribution to the homogeneous mixing of a polar substance with a nonpolar substance.

The addition of the hydrophobic resin brings about effects such as the control of static and dynamic contact angle formed between water and the resist film surface and the inhibition of outgas.

From the viewpoint of localization within the surface layer of a film, the hydrophobic resin preferably has any one or more kinds of groups among “fluorine atom”, “silicon atom”, and “CH₃ partial structure included in a side chain portion of the resin”, and more preferably has two or more kinds of groups among the above. Furthermore, it is preferable that the hydrophobic resin has a hydrocarbon group having 5 or more carbon atoms. These groups may be positioned in the main chain of the resin or may substitute a side chain of the resin.

In a case where the hydrophobic resin contains a fluorine atom and/or a silicon atom, the fluorine atom and/or the silicon atom in the hydrophobic resin may be contained in the main chain or the side chain of the resin.

In a case where the hydrophobic resin contains a fluorine atom, as a partial structure having the fluorine atom, a fluorine atom-containing alkyl group, a fluorine atom-containing cycloalkyl group, or a fluorine atom-containing aryl group is preferable.

The fluorine atom-containing alkyl group (preferably having 1 to 10 carbon atoms and more preferably having 1 to 4 carbon atoms) is a linear or branched alkyl group in which at least one hydrogen atom is substituted with a fluorine atom and which may further have a substituent other than a fluorine atom.

The fluorine atom-containing cycloalkyl group is a monocyclic or polycyclic cycloalkyl group in which at least one hydrogen atom is substituted with a fluorine atom and which may further have a substituent other than a fluorine atom.

Examples of the fluorine atom-containing aryl group include an aryl group in which at least one hydrogen atom is substituted with a fluorine atom, such as a phenyl group or a naphthyl group. The fluorine atom-containing aryl group may further have a substituent other than a fluorine atom.

Examples of the repeating unit having a fluorine atom or a silicon atom include the repeating units exemplified in paragraph “0519” of US2012/0251948A1.

As described above, it is also preferable that the hydrophobic resin contains a CH₃ partial structure in a side chain portion.

Herein, the CH₃ partial structure that the side chain portion of the hydrophobic resin has includes a CH₃ partial structure that an ethyl group, a propyl group, or the like has.

A methyl group directly bonded to the main chain of the hydrophobic resin (for example, an α-methyl group of a repeating unit having a methacrylic acid structure) makes a small contribution to the surface localization of the hydrophobic resin due to the influence of the main chain. Accordingly, such a methyl group is not included in the CH₃ partial structure.

Regarding the hydrophobic resin, the description in paragraphs “0348” to “0415” of JP2014-010245A can be referred to, and the entire contents thereof are incorporated into the present specification.

As the hydrophobic resin, in addition to the above resins, the resins described in JP2011-248019A, JP2010-175859A, and JP2012-032544A can also be preferably used.

Examples of the hydrophobic resin include resins represented by Formula (1b) to Formula (5b).

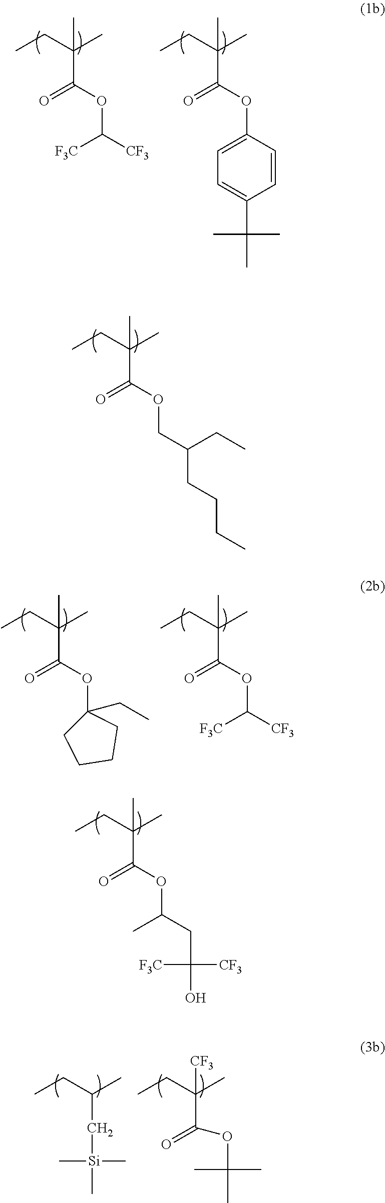

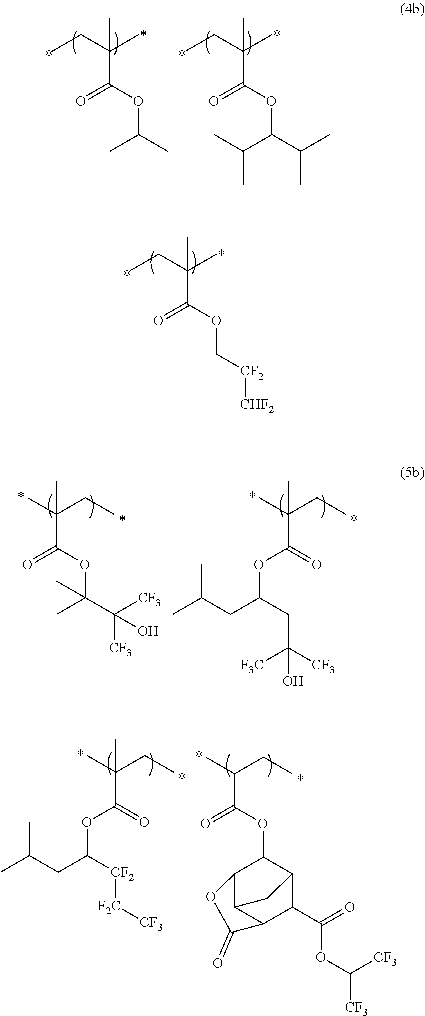

In a case where the resist composition contains the hydrophobic resin, the content of the hydrophobic resin with respect to the total solid content of the composition is preferably 0.01% to 20% by mass, and more preferably 0.1% to 15% by mass.

(Solvent)

The resist composition may contain a solvent. As the solvent, known solvents can be used without particular limitations.

The solvent contained in the resist composition may be the same as or different from the organic solvent contained in the pre-wet liquid.

The chemical liquid supplied by the present supply method can be used as a solvent contained in the resist composition.

The content of the solvent in the resist composition is not particularly limited. The resist composition preferably contains the solvent such that the total solid content of the resist composition is adjusted to 0.1% to 20% by mass, and more preferably contains the solvent such that the total solid content of the resist composition is adjusted to 0.5% to 10% by mass. One kind of solvent may be used singly, or two or more kinds of solvents may be used in combination. In a case where two or more kinds of solvents are used in combination, the total content thereof is preferably within the above range.

Examples of the solvent include the solvents described in JP2016-057614A, JP2014-219664A, JP2016-138219A, and JP2015-135379A.

(Other Additives)

As necessary, the resist composition may additionally contain a surfactant, an acid proliferation agent, a dye, a plasticizer, a photosensitizer, a light absorbing agent, an alkali-soluble resin other than the above resins, and/or a dissolution inhibitor.

In order to form a resist film (resist composition film) on a substrate by using the resist composition, a resist composition is prepared by means of the dissolving the aforementioned components in a solvent and the like and filtered using a filter as necessary, and then the substrate (pre-wetted substrate) is coated with the resist composition. The pore size of the filter is preferably 0.1 μm or less, more preferably 0.05 μm or less, and even more preferably 0.03 μm or less. The filter is preferably made of polytetrafluoroethylene, polyethylene, or nylon.

By an appropriate coating method such as spin coating, the substrate is coated with the resist composition. Then, the resist composition with which the substrate is coated is dried to form a resist film.

As a drying method, a method of heating and drying is used. The heating can be performed by a unit comprising a general exposure/development machine or the like, or may be performed using a hot plate or the like.

The heating temperature is preferably 80° C. to 180° C., more preferably 80° C. to 150° C., even more preferably 80° C. to 140° C., and particularly preferably 80° C. to 130° C. The heating time is preferably 30 to 1,000 seconds, more preferably 60 to 800 seconds, and even more preferably 60 to 600 seconds.

The film thickness of the resist film is, for example, 1 to 200 nm, and preferably 10 to 100 nm.

In the resist film forming method and/or the pattern forming method, an overlayer film (topcoat film) may be formed as the overlayer of the resist film. The overlayer film can be formed using, for example, a composition for forming an overlayer film containing a hydrophobic resin, a photoacid generator, and a basic compound.

<(C) Exposure Step>

The exposure step is a step of exposing the resist film. As the method of exposing the resist film, known methods can be used without particular limitation.

Examples of the method of exposing the resist film include a method of irradiating the resist film with actinic rays or radiation through a predetermined mask. In a case where the method of irradiating the resist film with electron beams is used, the resist film may be irradiated without the intervention of a mask (this is also called “direct imaging” in some cases)

The actinic rays or the radiation used for exposure is not particularly limited, and examples thereof include a KrF excimer laser, an ArF excimer laser, extreme ultraviolet (EUV), an electron beam (EB), and the like. Among these, extreme ultraviolet or an electron beam is preferable. The exposure may be immersion exposure.

(PEB step)

It is preferable that the aforementioned pattern forming method additionally includes a Post Exposure Bake (PEB) step of baking the resist film obtained after exposure before the exposure step and the development step. By the baking, the reaction in the exposed portion is accelerated, and either or both of sensitivity and pattern shape are further improved.

The heating temperature is preferably 80° C. to 150° C., more preferably 80° C. to 140° C., and even more preferably 80° C. to 130° C.

The heating time is preferably 30 to 1,000 seconds, more preferably 60 to 800 seconds, and even more preferably 60 to 600 seconds.

The heating can be performed by a unit comprising a general exposure⋅development machine, or may be performed using a hot plate or the like.

<(D) Development Step>

The development step is a step of developing the exposed resist film (hereinafter, referred to as “resist film obtained after exposure” as well) by using a developer.

As the development method, known development methods can be used without particular limitation. Examples of the development method include dipping method, a puddle method, a spray method, a dynamic dispense method, and the like.

Furthermore, the aforementioned pattern forming method may additionally have a step of substituting the developer with another solvent to stop the development after the development step.

The development time is not particularly limited, but is preferably 10 to 300 seconds in general and more preferably 10 to 120 seconds. The temperature of the developer is preferably 0° C. to 50° C., and more preferably 15° C. to 35° C. In the pattern forming method, the development step may be performed at least once or multiple times.

(Developer)

As the developer, known developers can be used without particular limitation. Examples of the developer include an alkaline developer and a developer containing an organic solvent (organic developer).

The chemical liquid supplied by the present supply method can be used as an organic solvent contained in an organic developer.

In the development step, both the development using a developer containing an organic solvent and development using an alkaline developer may be performed (so-called double development may be performed).

<(E) Rinsing Step>

It is preferable that the aforementioned pattern forming method additionally includes a rinsing step after the development step.

The rinsing step is a step of washing the wafer, which comprises the resist film obtained after development, by using a rinsing solution.

As the washing method, known washing methods can be used without particular limitation. Examples of the washing method include a rotation jetting method, a dipping method, a spray method, and the like.

Among these, it is preferable to use the rotation jetting method in which the wafer is washed and then rotated at a rotation speed of 2,000 to 4,000 rpm such that the rinsing liquid is removed from the substrate.

The rinsing time is preferably 10 to 300 seconds, more preferably 10 to 180 seconds, and even more preferably 20 to 120 seconds. The temperature of the rinsing liquid is preferably 0° C. to 50° C., and more preferably 15° C. to 35° C.

(Rinsing Liquid)

In a case where the wafer comprising the resist film is rinsed after the development using an alkaline developer, as the rinsing liquid, pure water is preferable. The rinsing liquid may be pure water containing a surfactant.

In a case where a wafer comprising a resist film is rinsed after development using an organic developer, as the rinsing liquid, a rinsing liquid containing an organic solvent is preferable. As the organic solvent contained in the rinsing liquid, for example, at least one kind of organic solvent is preferable which is selected from the group consisting of a hydrocarbon-based solvent, a ketone-based solvent, an ester-based solvent, an alcohol-based solvent, an amide-based solvent, and an ether-based solvent, at least one kind of organic solvent selected from the group consisting of a hydrocarbon-based solvent, an ether-based solvent, and a ketone-based solvent is more preferable, and at least one kind of organic solvent selected from the group consisting of a hydrocarbon-based solvent and an ether-based solvent is even more preferable.

It is preferable that the chemical liquid supplied by the present supply method be used as the rinsing liquid.

In a case where the developer containing an organic solvent is used in the development step, the aforementioned pattern forming method may have the rinsing step after the development step. However, from the viewpoint of throughput (productivity), the pattern forming method may not have the rinsing step.

As the pattern forming method that does not have a rinsing step, for example, the description in paragraphs “0014” to “0086” of JP2015-216403A can be cited, and the contents thereof are incorporated into the present specification.

As the rinsing solution, methyl isobutyl carbinol (MIBC) or the same liquid (particularly, butyl acetate) as the developer is also preferable.

<Other Steps>

The aforementioned pattern forming method may have other steps in addition to the steps described above. Examples of those other steps include a washing step using a supercritical fluid, a heating step, and the like.

The pattern forming method may also have a resist underlayer film-forming step of forming a resist underlayer film by using a composition for forming a resist underlayer film on the substrate having undergone the pre-wetting step. The resist underlayer film-forming step can be performed according to the method described in (B) resist film forming step described above. In addition, the pre-wetting step performed before the resist underlayer film-forming step can be performed according to the method described in (A) pre-wetting step described above.

(Removing Step Using Supercritical Fluid)

A removing step using a supercritical fluid is a step of removing the developer and/or the rinsing liquid having adhered to the pattern surface by using a supercritical fluid after the development treatment and/or the rinsing treatment.

(Heating Step)

The heating step is a step of heating the resist film to remove the solvent remaining in the pattern after the development step, the rinsing step, or the removing step using a supercritical fluid.

The heating temperature is not particularly limited, but is preferably 40° C. to 160° C., more preferably 50° C. to 150° C., and even more preferably 50° C. to 110° C.

The heating time is not particularly limited, but is preferably 15 to 300 seconds, and more preferably 15 to 180 seconds.

(BARC Composition Coating Step)

The pattern forming method may have a step of coating the wafer with a bottom of anti-reflection coating (BARC) composition before (B) resist film forming step. In addition, the BARC composition coating step may further have a step of removing the BARC composition with which the edge part (end part) of the wafer is unintentionally coated.

The chemical liquid can also be suitably used for other uses in addition to the manufacturing of semiconductor devices. The chemical liquid can be used as a developer or a rinsing liquid of polyimide, a resist for a sensor, a resist for a lens, and the like.

The chemical liquid can also be used as a solvent for medical uses or for washing. Particularly, the chemical liquid can be suitably used for washing members such as a container, a pipe, and a substrate (for example, a wafer, glass, or the like).

### EXAMPLES

Hereinafter, the present invention will be more specifically described based on examples. The materials, the amount and proportion thereof used, the details of treatments, the procedure of treatments, and the like shown in the following examples can be appropriately modified as long as the gist of the present invention is maintained. Therefore, the scope of the present invention is not limited to the following examples.

In various measurements, in a case where a component to be measured was outside the range that can be measured by each measurement apparatus (for example, in a case where the component is equal to or less than the measurement limit), by using a glass instrument thoroughly washed with the object to be measured (chemical liquid), the object to be measured is measured after being concentrated or diluted.

A supply device was prepared which comprises the storage tank 11, the gas pipe 12, the pipe line 13, the intermediate tank 14, the pipe line 15, the discharge unit 16, and the pump 17 and the filter unit 20 disposed on the pipe line 15 as shown in FIG. 1. In addition, a gas filter (“Wafergard III NF-750 in-line gas filter” manufactured by Entegris Inc.) was disposed on the upstream side of the storage tank 11 of the gas pipe 12.

[Raw Material]

(Pumping Gas)

In each of examples and comparative example, as a gas for feeding of a chemical liquid (pumping gas), the following gases were used.
Argon (Ar)
Nitrogen (N₂)
Helium (He)

(Organic Solvent)

In each of examples and comparative examples, as a chemical liquid, the following organic solvents were used.
Propylene glycol monomethyl ether acetate (PGMEA)
Hexane
4-Methyl-2-pentanol (MIBC)
1-Hexanol
Isopropanol (IPA)
Propylene glycol monoethyl ether (PGME)
Ethyl lactate (EL)
Butyl acetate (nBA)
Propylene carbonate
Ethyl propionate
Isoamyl acetate
2-Heptanone (MAK)
Methyl ethyl ketone (MEK)
Cyclohexanone
Cyclopentanone

(Content of Specific Metal Components)

The content of each type of metal component (metal ions and metal particles) in the chemical liquid was measured under the following conditions by using ICP-MS (“Agilent 8800 triple quadrupole ICP-MS (for semiconductor analysis, option #200)”).

As a sample introduction system, a quartz torch, a coaxial perfluoroalkoxyalkane (PFA) nebulizer (for self-suction), and a platinum interface cone were used. The measurement parameters of cool plasma conditions are as follows.
Output of Radio Frequency (RF) (W): 600
Flow rate of carrier gas (L/min): 0.7
Flow rate of makeup gas (L/min): 1
Sampling depth (mm): 18

(Moisture Content)

The moisture content in the chemical liquid was measured using a Karl Fischer moisture titrator (trade name “MKC-710M”, manufactured by KYOTO ELECTRONICS MANUFACTURING CO., LTD., Karl Fischer coulometric titration type)

(Content of Dioctyl Phthalate)

The content of dioctyl phthalate (DOP) in the chemical liquid was measured under the following conditions by using a gas chromatography-mass spectroscopy (trade name “GCMS-2020”, manufactured by Shimadzu Corporation).

Capillary column: InertCap 5MS/NP 0.25 mmI.D. ‘30 m df=0.25 μm

Sample introduction method: slit 75 kPa constant pressure

Vaporizing chamber temperature: 230° C.

Column oven temperature: 80° C. (2 min)-500° C. (13 min) heating rate 15° C./min

Carrier gas: helium

Septum purge flow rate: 5 mL/min

Split ratio: 25:1

Interface temperature: 250° C.

Ion source temperature: 200° C.

Measurement mode: Scan m/z=85 to 1,000

Amount of sample introduced: 1 μL

(Filter)

In each of examples and comparative examples, a filter constituted with the following material was used.
Polytetrafluoroethylene (PTFE)
Polyethylene (PE)
Nylon

[Preparation of Chemical Liquid]

A commercially available organic solvent was prepared and purified using the following purification device, thereby preparing a chemical liquid used in each of examples and comparative examples.

First, a purification device was prepared which comprises container, a discharge unit, a pipe connecting the container to the discharge unit, a filtering device disposed on the pipe, and a return pipe connecting the container to a pipe positioned on the downstream side from the filtering device. The filtering device is composed of a plurality of filter units arranged in series on the pipe and does not have an adjusting valve. The filtering device comprised, for example, a filter unit having the following filters in order from the upstream side (primary side).
Polypropylene filter (pore diameter: 200 nm, porous membrane)
Polyfluorocarbon filter having an ion exchange group (pore diameter: 100 nm, fiber membrane consisting of a polymer of PTFE and polyethylene sulfonate (PES))
Nylon filter (pore diameter: 3 nm, fiber membrane)

The return pipe has a function of returning the organic solvent that has passed through the filtration device to the container.

The liquid contact portion of the purification device was thoroughly washed with an organic solvent, and then the chemical liquid was prepared using the washed purification device.

After the container was filled with the organic solvent, a pump disposed on a pipe connecting the container to the filtration device was operated to send the organic solvent from the container to the filtration device. The organic solvent was filtered by the filter unit in the filtration device, and then the filtered organic solvent was returned to the container through the return pipe. The filtration using the filter unit and the return of the filtered organic solvent were repeated, and then the filtered organic solvent was discharged from the discharge unit, thereby obtaining a chemical liquid used in each of examples and comparative examples.

In addition, for each of examples and comparative examples, the type and number of filters that the filtering device comprises in the filtration device in the aforementioned filtration treatment and the number of times the filtration is repeated were appropriately changed, thereby preparing chemical liquids having the compositions shown in Table 1.

### Example 1

A filter cartridge having a filter having a pore diameter of 2 nm was housed in a filter unit 20 disposed on the pipe line 15 of the supply device 10. The material (filter medium) constituting the filter was polytetrafluoroethylene (PTFE).

The content of each of the specific metal components, moisture, and dioctyl phthalate in each chemical liquid prepared by the above preparation method was measured by the above measuring method, and then the chemical liquid is stored in the storage tank 11.

As a raw material gas, Ar was sent into the gas pipe 12 and passed through a gas filter to prepare a pumping gas. The obtained pumping gas was introduced into the storage tank 11 from the top of the storage tank 11 connected to the gas pipe 12. In this way, the pressure of the gas accumulated in the head space of the upper part of the storage tank 11 was increased such that the surface of the chemical liquid stored in the storage tank 11 was pressurized. By the pressure difference between the inside of the storage tank 11 and the inside of the intermediate tank 14 generated by the pressurization, the chemical liquid stored in the storage tank 11 was sent (pumped) to the intermediate tank 14 through the pipe line 13. Then, the pump 17 disposed on the pipe line 15 connecting the intermediate tank 14 to the discharge unit 16 was operated such that the chemical liquid stored in the intermediate tank 14 was discharged from the discharge unit 16. At this time, by passing the chemical liquid through the filter unit 20 disposed in the pipe line 15, a filtration treatment was performed on the chemical liquid as a purification step.

### Examples 2 to 65 and Comparative Examples 1 to 5

A purified chemical liquid was obtained by supplying the chemical liquid according to the same method described in Example 1, except that the pumping gas, chemical liquid, and filter described in Table 1 were used.

The chemical liquid obtained in each of examples and comparative examples was evaluated as below.

[Evaluation]

(Evaluation of Elution Amount of Impurity)

For the supply method of each of examples and comparative examples, the content of an organic impurity in the chemical liquid was measured by the following method. In this way, the amount of an organic impurity eluted into the chemical liquid from the liquid contact portion of the pipe line or the like of the supply device in each supply method was measured.

First, a silicon oxide film substrate having a diameter of 300 mm was prepared. By using a wafer surface inspection device (Surfscan SPS; manufactured by KLA-Tencor), the number of organic residues having a diameter of 19 nm or more present on the substrate was measured (the measured number of organic residues is adopted as an initial value).

Then, the substrate was set in a spin jet device, and in a state where the substrate was being rotated, the chemical liquid not yet being used in each supply method was jetted to the surface of the substrate at a flow rate of 1 mL/s.

Thereafter, the substrate was spin-dried. By using the aforementioned inspection device, the number of organic residues having a diameter of 19 nm or more present on the substrate having been coated with the chemical liquid was measured (the measured number of organic residues is adopted as a measured value). A difference between the initial value and the measured value (measured value−initial value) was calculated and adopted as an organic impurity amount A1 derived from the chemical liquid not yet being used in each supply method.

Based on the coordinate data calculated by the aforementioned inspection device, for defects newly increased after the substrate was coated with the chemical liquid, elemental analysis was performed by energy dispersive X-ray spectrometry (EDX) by using a defect analyzer (SEM Vision G6; manufactured by Applied Materials, Inc.). By this method, it has been confirmed that the particles measured as an organic impurity do not contain a metal component.

A sample for measuring an elution amount of each of examples and comparative examples was obtained by the same method as the supply method of each of examples and comparative examples described above, except that the filter cartridge having a filter was not housed in the filter unit, and a chemical liquid purification step using a filter was not performed.

For each sample, the initial value and the measured value were measured according to the same method as described above, and it has been confirmed that the measured particles are an organic impurity that does not contain a metal component. The difference between the obtained initial value and measured value (measured value−initial value) was calculated and adopted as an organic impurity amount A2 derived from each sample.

From the amount of organic impurity amount A1 derived from the chemical liquid not yet being supplied and the organic impurity amount A2 derived from the sample, an elution amount of impurities (number/wafer) in the supply method of each of examples and comparative examples was calculated using Formula (A1−A2). The calculated elution amount of impurities is shown in Table 1.

The smaller the elution amount of impurities, the further the elution into the chemical liquid from the liquid contact portion of the pipe line or the like of the supply device is suppressed by the supply method.

(Evaluation of Removing Performance of Filter)

For the supply method of each of examples and comparative examples, the removing performance of the filter in the purification step of filtering the chemical liquid was evaluated by the following method.

For Examples 1 to 65 and Comparative Examples 1 to 5, by using the chemical liquid obtained by the aforementioned supply method having the chemical liquid purification step using a filter, the amount of an organic impurity was measured in the same manner as in the aforementioned test for evaluating the elution amount of impurities.

That is, for the chemical liquid of each of examples and comparative examples, the initial value and the measured value were measured according to the same method as described above, and it has been confirmed that the measured particles are an organic impurity that does not contain a metal component. The difference between the obtained initial value and measured value (measured value−initial value) was calculated and adopted as an organic impurity amount A3 derived from each chemical liquid.

From the organic impurity amount A2 derived from the sample obtained by the supply method that does not have the purification step and an organic impurity amount A3 derived from the chemical liquid obtained by the supply method having the purification step, a removal rate (%) of impurities removed by the purification step that each supply method has was calculated using Formula ((A2−A3)/A2). The calculated removal rate of impurities (filter removal rate) is shown in Table 1.

The higher the filter removal rate, the higher the organic impurity removing performance of the purification step that the supply method has.

Table 1 shows the composition of the pumping gas, the composition of the chemical liquid, and the filter used in each of examples and comparative examples and the evaluation results.

The column of “Type” of “Pumping gas” in Table 1 shows the type of pumping gas used in each of examples and comparative examples.

The column of “Gas filter” shows whether or not the supply device used in each of examples and comparative examples has a gas filter. “Present” written in the column of Gas filter means that a pumping gas was prepared (purified) by passing a gas through a gas filter provided on the gas pipe. “Absent” written in the column of Gas filter means that a pumping gas shown in Table 1 was prepared by purification in advance without performing the purification of the pumping gas in the supply device.

The column of “Moisture content (ppm)” shows the content (unit: ppm by mass) of moisture contained in the pumping gas used in each of examples and comparative examples.

The “purity” column indicates the purity of the pumping gas used in each Example and each Comparative Example. That is, “2N”, “3N”, and “5N” written in the column of “Purity” mean that the purity of the used pumping gas was 99% by volume (2N), 99.9% by volume (3N), and 99.999% by volume (5N), respectively.

The column of “Organic solvent” of “Chemical liquid” in Table 1 shows the type of organic solvent used in each of examples and comparative examples. In all the examples and comparative examples, the content of the organic solvent contained in the chemical liquid was 99.5% by mass or more.

The column of “Specific metal content (ppt)” shows the total content (unit: ppt by mass) of an Fe component (Fe particles and Fe ions), a Cr component (Cr particles and Cr ions), a Ni component (Ni particles and Ni ions), and an Al component (Al particles Al ions) component) with respect to the total mass of the chemical liquid.

The content of metal components other than the specific metal components contained in the chemical liquid used in each of examples was measured. As a result, in all the examples, the content of the aforementioned other metal components was 10 ppt by mass or less with respect to the total mass of the chemical liquid.

The column of “Moisture content (%)” shows the content of water (unit: % by mass) with respect to the total mass of the chemical liquid used in each of examples and comparative examples.

The column of “DOP (ppb)” shows the content of dioctyl phthalate (unit: ppb by mass) with respect to the total mass of the chemical liquid used in each of examples and comparative examples.

The column of “Material” of “Filter” in Table 1 shows the material of the filter medium constituting the filter used in the chemical liquid purification step in the supply device, and the column of “Pore diameter” shows the pore diameter of each filter.

TABLE 1

| | | | | | | | | | | | Evaluation result | |
|---|---|---|---|---|---|---|---|---|---|---|---|---|
| | | | | | Chemical liquid | | | | | | Elution | |
| | Pumping gas | | | | | Specific | | | Filter | | amount of | Filter |
| | | | Moisture | | | metal | Moisture | | | Pore | impurity | removal |
| | | Gas | content | | Organic | content | content | DOP | | diameter | (number/ | rate |
| | Type | filter | (ppm) | Purity | solvent | (ppt) | (%) | (ppb) | Material | (nm) | wafer) | (%) |
| Example 1 | Ar | Present | 0.01 | 5N | PGMEA | 0.2 | 0.01 | 1 | PTFE | 2 | 36 | 99.0 |
| Example 2 | N₂ | Present | 0.01 | 5N | PGMEA | 0.2 | 0.01 | 1 | PTFE | 2 | 57 | 95.8 |
| Example 3 | He | Present | 0.01 | 5N | PGMEA | 40 | 0.01 | 1 | PTFE | 2 | 73 | 92.0 |
| Example 4 | N₂ | Present | 0.025 | 5N | PGMEA | 0.2 | 0.01 | 1 | PTFE | 2 | 61 | 93.0 |
| Example 5 | N₂ | Present | 0.45 | 5N | PGMEA | 0.2 | 0.01 | 1 | PTFE | 2 | 250 | 90.0 |
| Example 6 | N₂ | Present | 0.97 | 5N | PGMEA | 0.2 | 0.01 | 1 | PTFE | 2 | 371 | 86.9 |
| Example 7 | N₂ | Present | 0.0044 | 5N | PGMEA | 0.2 | 0.01 | 1 | PTFE | 2 | 357 | 88.2 |
| Example 8 | N₂ | Present | 0.03 | 5N | PGMEA | 52 | 0.01 | 1 | PTFE | 2 | 247 | 92.4 |
| Example 9 | N₂ | Present | 0.5 | 5N | PGMEA | 24 | 0.01 | 1 | PTFE | 2 | 366 | 87.8 |
| Example 10 | N₂ | Present | 1 | 5N | PGMEA | 48 | 0.01 | 1 | PTFE | 2 | 453 | 85.6 |
| Example 11 | N₂ | Present | 0.009 | 5N | PGMEA | 48 | 0.01 | 1 | PTFE | 2 | 249 | 90.8 |
| Example 12 | N₂ | Present | 0.005 | 5N | PGMEA | 48 | 0.01 | 1 | PTFE | 2 | 250 | 89.4 |
| Example 15 | N₂ | Present | 0.00001 | 5N | PGMEA | 0.28 | 0.01 | 1 | PTFE | 2 | 356 | 86.5 |
| Example 14 | N₂ | Present | 0.01 | 3N | PGMEA | 0.28 | 0.01 | 1 | PTFE | 2 | 356 | 93.7 |
| Example 15 | N₂ | Present | 0.01 | 2N | PGMEA | 0.28 | 0.01 | 1 | PTFE | 2 | 356 | 88.5 |
| Example 15 | N₂ | Present | 0.01 | 5N | PGMEA | 55 | 0.01 | 1 | PTFE | 2 | 72 | 95.2 |
| Example 17 | N₂ | Present | 0.01 | 5N | PGMEA | 62 | 0.01 | 1 | PTFE | 2 | 69 | 93.3 |
| Example 18 | N₂ | Present | 0.01 | 5N | PGMEA | 400 | 0.01 | 1 | PTFE | 2 | 70 | 92.8 |
| Example 19 | N₂ | Present | 0.01 | 5N | PGMEA | 409 | 0.01 | 1 | PTFE | 2 | 64 | 90.0 |
| Example 20 | N₂ | Present | 0.01 | 5N | PGMEA | 631 | 0.01 | 1 | PTFE | 2 | 71 | 89.4 |
| Example 21 | N₂ | Present | 0.01 | 5N | PGMEA | 1150 | 0.01 | 1 | PTFE | 2 | 71 | 88.4 |
| Example 22 | N₂ | Present | 0.01 | 5N | PGMEA | 1280 | 0.01 | 1 | PTFE | 2 | 56 | 81.8 |
| Example 23 | N₂ | Present | 0.01 | 5N | PGMEA | 0.16 | 0.01 | 1 | PTFE | 2 | 57 | 91.2 |
| Example 24 | N₂ | Present | 0.01 | 5N | PGMEA | 0.036 | 0.01 | 1 | PTFE | 2 | 56 | 86.1 |
| Example 25 | N₂ | Present | 0.01 | 5N | PGMEA | 0.06 | 0.01 | 1 | PTFE | 2 | 68 | 91.5 |

TABLE 2

| | | | | | | | | | | | Evaluation result | |
|---|---|---|---|---|---|---|---|---|---|---|---|---|
| | | | | | Chemical liquid | | | | | | Elution | |
| | Pumping gas | | | | | Specific | | | Filter | | amount of | Filter |
| | | | Moisture | | | metal | Moisture | | | Pore | impurity | removal |
| | | Gas | content | | Organic | content | content | DOP | | diameter | (number/ | rate |
| | Type | filter | (ppm) | Purity | solvent | (ppt) | (%) | (ppb) | Material | (nm) | wafer) | (%) |
| Example 26 | N₂ | Present | 0.01 | 5N | PGMEA | 40 | 0.015 | 1 | PTFE | 2 | 57 | 93.7 |
| Example 27 | N₂ | Present | 0.01 | 5N | PGMEA | 44 | 0.028 | 1 | PTFE | 2 | 63 | 92.3 |
| Example 28 | N₂ | Present | 0.01 | 5N | PGMEA | 12 | 0.032 | 1 | PTFE | 2 | 62 | 89.0 |
| Example 29 | N₂ | Present | 0.01 | 5N | PGMEA | 44 | 0.0005 | 1 | PTFE | 2 | 72 | 88.2 |
| Example 30 | N₂ | Present | 0.01 | 5N | PGMEA | 16 | 0.0009 | 1 | PTFE | 2 | 71 | 91.2 |
| Example 31 | N₂ | Present | 0.01 | 5N | PGMEA | 44 | 0.01 | 5 | PTFE | 2 | 60 | 92.5 |
| Example 32 | N₂ | Present | 0.01 | 5N | PGMEA | 48 | 0.01 | 10 | PTFE | 2 | 62 | 91.8 |
| Example 33 | N₂ | Present | 0.01 | 5N | PGMEA | 52 | 0.01 | 11 | PTFE | 2 | 68 | 90.2 |
| Example 34 | N₂ | Present | 0.01 | 5N | PGMEA | 52 | 0.01 | 0.009 | PTFE | 2 | 71 | 90.9 |
| Example 35 | N₂ | Present | 0.01 | 5N | PGMEA | 52 | 0.01 | 0.001 | PTFE | 2 | 64 | 89.1 |
| Example 36 | N₂ | Present | 0.01 | 5N | PGMEA | 52 | 0.01 | 0.0005 | PTFE | 2 | 62 | 85.3 |
| Example 37 | N₂ | Present | 0.01 | 5N | Hexane | 0.05 | 0.01 | 1 | PTFE | 2 | 76 | 94.4 |
| Example 38 | N₂ | Present | 0.01 | 5N | MIBC | 3 | 0.01 | 1 | PTFE | 2 | 60 | 94.3 |
| Example 39 | N₂ | Present | 0.01 | 5N | 1-Hexanol | 5 | 0.01 | 1 | PTFE | 2 | 74 | 94.9 |
| Example 40 | N₂ | Present | 0.01 | 5N | IPA | 6 | 0.01 | 1 | PTFE | 2 | 52 | 95.9 |
| Example 41 | N₂ | Present | 0.01 | 5N | PGME | 12 | 0.01 | 1 | PTFE | 2 | 64 | 94.1 |
| Example 42 | N₂ | Present | 0.01 | 5N | EL | 3 | 0.01 | 1 | PTFE | 2 | 64 | 95.8 |
| Example 43 | N₂ | Present | 0.01 | 5N | nBA | 15 | 0.01 | 1 | PTFE | 2 | 71 | 94.7 |
| Example 44 | N₂ | Present | 0.01 | 5N | Propylene | 1 | 0.01 | 1 | PTFE | 2 | 74 | 95.1 |
| | | | | | carbonate | | | | | | | |
| Example 45 | N₂ | Present | 0.01 | 5N | Ethyl | 0.2 | 0.01 | 1 | PTFE | 2 | 65 | 94.4 |
| | | | | | propionate | | | | | | | |
| Example 46 | N₂ | Present | 0.01 | 5N | Isoamyl | 0.9 | 0.01 | 1 | PTFE | 2 | 71 | 94.8 |
| | | | | | acetate | | | | | | | |
| Example 47 | N₂ | Present | 0.01 | 5N | MAK | 5 | 0.01 | 1 | PTFE | 2 | 71 | 95.2 |
| Example 48 | N₂ | Present | 0.01 | 5N | MEK | 2 | 0.01 | 1 | PTFE | 2 | 71 | 95.7 |
| Example 49 | N₂ | Present | 0.01 | 5N | Cyclo- | 1 | 0.01 | 1 | PTFE | 2 | 62 | 94.5 |
| | | | | | hexamone | | | | | | | |
| Example 50 | N₂ | Present | 0.01 | 5N | Cyclo- | 1 | 0.01 | 1 | PTFE | 2 | 58 | 94.1 |
| | | | | | pentanone | | | | | | | |

TABLE 3

| | | | | | | | | | | | Evaluation result | |
|---|---|---|---|---|---|---|---|---|---|---|---|---|
| | | | | | Chemical liquid | | | | | | Elution | |
| | Pumping gas | | | | | Specific | | | Filter | | amount of | Filter |
| | | | Moisture | | | metal | Moisture | | | Pore | impurity | removal |
| | | Gas | content | | Organic | content | content | DOP | | diameter | (number/ | rate |
| | Type | filter | (ppm) | Purity | solvent | (ppt) | (%) | (ppb) | Material | (nm) | wafer) | (%) |
| Example 51 | N₂ | Present | 0.01 | 5N | PGMEA | 4 | 0.01 | 1 | PTFE | 5 | 60 | 94.8 |
| Example 52 | N₂ | Present | 0.01 | 5N | PGMEA | 4 | 0.01 | 1 | PTFE | 10 | 54 | 95.1 |
| Example 53 | N₂ | Present | 0.01 | 5N | PGMEA | 4 | 0.01 | 1 | PTFE | 20 | 70 | 95.6 |
| Example 54 | N₂ | Present | 0.01 | 5N | PGMEA | 4 | 0.01 | 1 | PTFE | 50 | 67 | 94.4 |
| Example 55 | N₂ | Present | 0.01 | 5N | PGMEA | 4 | 0.01 | 1 | PE | 1 | 67 | 94.3 |
| Example 56 | N₂ | Present | 0.01 | 5N | PGMEA | 4 | 0.01 | 1 | PE | 3 | 58 | 95.0 |
| Example 57 | N₂ | Present | 0.01 | 5N | PGMEA | 4 | 0.01 | 1 | PE | 5 | 56 | 94.4 |
| Example 58 | N₂ | Present | 0.01 | 5N | PGMEA | 4 | 0.01 | 1 | PE | 10 | 69 | 95.9 |
| Example 59 | N₂ | Present | 0.01 | 5N | PGMEA | 4 | 0.01 | 1 | PE | 20 | 72 | 94.3 |
| Example 60 | N₂ | Present | 0.01 | 5N | PGMEA | 4 | 0.01 | 1 | PE | 50 | 78 | 94.7 |
| Example 61 | N₂ | Present | 0.01 | 5N | PGMEA | 4 | 0.01 | 1 | PP | 50 | 55 | 95.7 |
| Example 62 | N₂ | Present | 0.01 | 5N | PGMEA | 4 | 0.01 | 1 | Nylon | 5 | 72 | 95.7 |
| Example 63 | N₂ | Present | 0.01 | 5N | PGMEA | 4 | 0.01 | 1 | Nylon | 20 | 63 | 94.2 |
| Example 64 | N₂ | Present | 0.01 | 5N | PGMEA | 16 | 0.01 | 1 | Absent | — | 69 | 0.0 |
| Example 65 | N₂ | Absent | 1 | 5N | PGMEA | 48 | 0.01 | 1 | PTFE | 2 | 453 | 85.8 |
| Comparative | N₂ | Present | 1.1 | 5N | PGMEA | 32 | 0.01 | 1 | PTFE | 2 | 860 | 78.5 |
| Example 1 | | | | | | | | | | | | |
| Comparative | N₂ | Present | 1.5 | 5N | PGMEA | 48 | 0.01 | 1 | PTFE | 2 | 1065 | 73.3 |
| Example 2 | | | | | | | | | | | | |
| Comparative | N₂ | Present | 0.000089 | 5N | PGMEA | 8 | 0.01 | 1 | PTFE | 2 | 772 | 76.3 |
| Example 3 | | | | | | | | | | | | |
| Comparative | N₂ | Present | 0.000005 | 5N | PGMEA | 52 | 0.01 | 1 | PTFE | 2 | 973 | 70.3 |
| Example 4 | | | | | | | | | | | | |
| Comparative | N₂ | Present | 3 | 5N | PGMEA | 4 | 0.01 | 1 | PTFE | 2 | 1364 | 63.7 |
| Example 5 | | | | | | | | | | | | |

As shown in Table 1, it has been confirmed that the chemical liquid supply method of Examples 1 to 65 is more effective in reducing the amount of an organic impurity eluted into the chemical liquid from a pipe line, compared to the chemical liquid supply method of Comparative Examples 1 to 5.

### EXPLANATION OF REFERENCES

10: supply device
11: storage tank
12: gas pipe
12a: gas introduction port
13, 15: pipe line
14: intermediate tank
16: discharge port
17: pump
20: filter unit
21: gas filter

What is claimed is:

1. A chemical liquid supply method of supplying a chemical liquid containing an organic solvent through a pipe line that is provided in an apparatus for semiconductor devices, the chemical liquid supply method comprising:
a gas pumping step of sending the chemical liquid by pressurization using a gas,
wherein a moisture content in the gas is 0.00001 to 1 ppm by mass with respect to a total mass of the gas.

2. The chemical liquid supply method according to claim 1,
wherein a purity of the gas is 99.9% by volume or more.

3. The chemical liquid supply method according to claim 1,
wherein the moisture content in the gas is 0.005 to 0.5 ppm by mass with respect to the total mass of the gas.

4. The chemical liquid supply method according to claim 1,
wherein the moisture content in the gas is 0.01 to 0.03 ppm by mass with respect to the total mass of the gas.

5. The chemical liquid supply method according to claim 1,
wherein a purity of the gas is 99.999% by volume or more.

6. The chemical liquid supply method according to claim 1,
wherein the gas includes at least one gas selected from the group consisting of nitrogen and argon.

7. The chemical liquid supply method according to claim 1,
wherein the organic solvent is at least one compound selected from the group consisting of propylene glycol monomethyl ether, propylene glycol monoethyl ether, propylene glycol monopropyl ether, propylene glycol monomethyl ether acetate, ethyl lactate, methyl methoxypropionate, ethyl propionate, cyclopentanone, cyclohexanone, γ-butyrolactone, diisoamyl ether, butyl acetate, isoamyl acetate, isopropanol, 4-methyl-2-pentanol, 1-hexanol, dimethylsulfoxide, n-methyl-2-pyrrolidone, diethylene glycol, ethylene glycol, dipropylene glycol, propylene glycol, ethylene carbonate, propylene carbonate, sulfolane, cycloheptanone, 2-heptanone, methyl ethyl ketone, hexane, and a combination of these.

8. The chemical liquid supply method according to claim 1, further comprising:
a chemical liquid preparation step of preparing the chemical liquid in a storage tank that is in communication with the pipe line,
wherein the gas pumping step is a step of sending the chemical liquid from the storage tank through the pipe line by introducing the gas into the storage tank.

9. The chemical liquid supply method according to claim 1, further comprising:
a purification step of filtering the chemical liquid sent by the gas pumping step by using a filter.

10. The chemical liquid supply method according to claim 9,
wherein a total content of a Fe component, a Cr component, a Ni component, and an Al component in the chemical liquid filtered by the purification step is 0.04 to 1,200 ppt by mass with respect to a total mass of the chemical liquid.

11. The chemical liquid supply method according to claim 9,
wherein a total content of a Fe component, a Cr component, a Ni component, and an Al component in the chemical liquid filtered by the purification step is 0.2 to 400 ppt by mass with respect to a total mass of the chemical liquid.

12. The chemical liquid supply method according to claim 9,
wherein a total content of a Fe component, a Cr component, a Ni component, and an Al component in the chemical liquid filtered by the purification step is 0.2 to 60 ppt by mass with respect to a total mass of the chemical liquid.

13. The chemical liquid supply method according to claim 9,
wherein a moisture content in the chemical liquid filtered by the purification step is 0.0005% to 0.03% by mass with respect to a total mass of the chemical liquid.

14. The chemical liquid supply method according to claim 9,
wherein a moisture content in the chemical liquid filtered by the purification step is 0.001% to 0.02% by mass with respect to a total mass of the chemical liquid.

15. The chemical liquid supply method according to claim 9,
wherein a moisture content in the chemical liquid filtered by the purification step is 0.001% to 0.01% by mass with respect to a total mass of the chemical liquid.

16. The chemical liquid supply method according to claim 9,
wherein a content of dioctyl phthalate in the chemical liquid filtered by the purification step is 0.001 to 10 ppb by mass with respect to a total mass of the chemical liquid.

17. The chemical liquid supply method according to claim 9,
wherein a content of dioctyl phthalate in the chemical liquid filtered by the purification step is 0.01 to 5 ppb by mass with respect to a total mass of the chemical liquid.

18. The chemical liquid supply method according to claim 9,
wherein a content of dioctyl phthalate in the chemical liquid filtered by the purification step is 0.01 to 1 ppb by mass with respect to a total mass of the chemical liquid.

19. The chemical liquid supply method according to claim 1, further comprising:
a gas purification step of purifying a raw material gas by using a gas filter,
wherein the gas purified by the gas purification step is used in the gas pumping step.

20. A pattern forming method comprising:
a pre-wetting step of bringing a pre-wet liquid into contact with a substrate;
a resist film forming step of forming a resist film on the substrate by using a resist composition;
a step of exposing the resist film;
a development step of developing the exposed resist film by using a developer to form a resist pattern; and
a rinsing step of bringing a rinsing liquid into contact with the substrate on which the resist pattern is formed,
wherein at least one liquid selected from the group consisting of the pre-wet liquid, the developer, and the rinsing liquid is the chemical liquid supplied by the supply method according to claim 1.
